(19) United States
(12) Patent Application Publication
(10) Pub. No.: US 2024/0231235 A1
(43) Pub. Date: Jul. 11, 2024

(54) METHOD FOR TESTING PHOTOSENSITIVE COMPOSITION AND METHOD FOR PRODUCING PHOTOSENSITIVE COMPOSITION

(71) Applicant: FUJIFILM Corporation, Tokyo (JP)

(72) Inventors: Kei YAMAMOTO, Haibara-gun (JP); Naohiro TANGO, Haibara-gun (JP); Michihiro SHIRAKAWA, Haibara-gun (JP)

(73) Assignee: FUJIFILM Corporation, Tokyo (JP)

(21) Appl. No.: 18/610,588

(22) Filed: Mar. 20, 2024

Related U.S. Application Data
(63) Continuation of application No. PCT/JP2022/035023, filed on Sep. 20, 2022.

(30) Foreign Application Priority Data
Sep. 30, 2021 (JP) 2021-161670

(51) Int. Cl. G03F 7/30; G03F 7/32

(52) U.S. Cl. CPC G03F 7/3028; G03F 7/325

(57) ABSTRACT

Provided are a method for testing a photosensitive composition and a method for producing a photosensitive composition that can easily test whether or not the photosensitive composition exhibits a predetermined LWR. A method for testing a photosensitive composition according to the present invention has a step 1 of using a reference photosensitive composition to form a resist film, bringing the resist film into contact with a treatment liquid, and measuring a dissolution rate of the resist film to obtain reference data; a step 2 of using a photosensitive composition for measurement to form a resist film, bringing the resist film into contact with a treatment liquid, and measuring a dissolution rate of the resist film to obtain measurement data; and a step 3 of performing comparison between the reference data and the measurement data to determine whether or not an allowable range is satisfied, wherein the treatment liquid includes an organic solvent and a metal X, the organic solvent does not include an aromatic hydrocarbon and includes an aliphatic hydrocarbon, and a mass ratio of a content of the aromatic hydrocarbon to a content of the metal X is 5.0×10² to 5.0×10¹².

### CROSS-REFERENCE TO RELATED APPLICATIONS

This application is a Continuation of PCT International Application No. PCT/JP2022/035023 filed on Sep. 20, 2022, which claims priority under 35 U.S.C. § 119(a) to Japanese Patent Application No. 2021-161670 filed on Sep. 30, 2021. The above applications are hereby expressly incorporated by reference, in their entirety, into the present application.

### BACKGROUND OF THE INVENTION

### 1. Field of the Invention

The present invention relates to a method for testing a photosensitive composition including a photoacid generator and an acid decomposable resin having a group that is decomposed by the action of an acid to generate a polar group, and a method for producing a photosensitive composition.

### 2. Description of the Related Art

In fabrication processes for semiconductor devices such as ICs (Integrated Circuits or integrated circuits) or LSIs (Large Scale Integrated circuits or large scale integrated circuits), microprocessing by lithography using photosensitive compositions has been performed. In recent years, with an increase in the degree of integration of integrated circuits, formation of ultrafine patterns in the submicron range or the quarter micron range has come to be in demand. With this, there is also a trend for exposure wavelengths toward shorter wavelengths from the g-line to the i-line further to the ArF excimer laser beam and the KrF excimer laser beam. Further, currently, lithography using, instead of excimer laser beams, an electron beam or EUV (Extreme Ultra Violet or extreme ultra violet) light is also being developed.

For example, JP2020-126143A discloses a resist composition including a photoacid generator used for photolithography using high-energy beams such as an ArF excimer laser beam, a KrF excimer laser beam, an electron beam, and extreme ultraviolet rays as light sources.

### SUMMARY OF THE INVENTION

Photosensitive compositions desirably have small differences in performance among production lots. For this reason, in production of photosensitive compositions, attempts have been made to produce photosensitive compositions that exhibit the same performance in any production lot as in the other production lots. In this case, in order to determine whether or not the newly produced photosensitive composition exhibits the same performance as the photosensitive composition of the previous production lot, a resist pattern is formed and LWR (line width roughness) thereof is measured in some cases.

On the other hand, in order to measure LWR, as described above, formation of a resist film needs to be followed by formation of a resist pattern. Thus, the procedures of measuring the LWR are complicated, and a method that can more simply determine whether or not a photosensitive composition exhibits a predetermined LWR has been in demand.

An object of the present invention is to provide a method for testing a photosensitive composition and a method for producing a photosensitive composition that can easily test whether or not the photosensitive composition exhibits a predetermined LWR.

The inventors of the present invention have found that the following features can address the above-described object.

[1]

A method for testing a photosensitive composition, the method having:

a step 1 of using a reference photosensitive composition including an acid decomposable resin having a group that is decomposed by an action of an acid to generate a polar group and a photoacid generator, to form a resist film on a substrate 1, bringing the resist film on the substrate 1 into contact with a treatment liquid, and measuring a dissolution rate of the resist film on the substrate 1, to obtain reference data;

a step 2 of using a photosensitive composition for measurement including components of the same types as types of components included in the reference photosensitive composition, to form a resist film on a substrate 2, bringing the resist film on the substrate 2 into contact with a treatment liquid, and measuring a dissolution rate of the resist film on the substrate 2, to obtain measurement data; and

a step 3 of performing comparison between the reference data and the measurement data to determine whether or not an allowable range is satisfied,

wherein the treatment liquid includes an aromatic hydrocarbon, an organic solvent, and a metal X,

the organic solvent does not include the aromatic hydrocarbon and includes an aliphatic hydrocarbon,

the metal X is at least one metal selected from the group consisting of Al, Fe, and Ni, and a mass ratio of a content of the aromatic hydrocarbon to a content of the metal X is 5.0×10⁴ to 2.0×10¹⁰.

[2]

The method for testing a photosensitive composition according to [1], wherein, in the step 3, when the measurement data is out of the allowable range, component adjustment of the photosensitive composition for measurement is performed.

[3]

The method for testing a photosensitive composition according to [1] or [2], wherein, in the step 1 and the step 2, the resist film on the substrate 1 and the resist film on the substrate 2 are each an exposed resist film provided by forming the resist film and subsequently subjecting an entire surface of the resist film to exposure.

[4]

The method for testing a photosensitive composition according to [3], wherein the exposure in the step 1 and the step 2 is performed using any one of a KrF excimer laser beam, an ArF excimer laser beam, an electron beam, and an extreme ultraviolet ray.

[5]

The method for testing a photosensitive composition according to any one of [3] to [4], wherein the acid decomposable resin includes a repeating unit having a phenolic hydroxyl group.

[6]

The method for testing a photosensitive composition according to any one of [1] to [5], wherein the aliphatic hydrocarbon is undecane, and

the organic solvent further includes butyl acetate.

[7]

The method for testing a photosensitive composition according to [6], wherein a ratio of a content of the butyl acetate to a content of the undecane is 65/35 to 99/1.

[8]

The method for testing a photosensitive composition according to [7], wherein the ratio of the content of the butyl acetate to the content of the undecane is 90/10.

[9]

The method for testing a photosensitive composition according to any one of [1] to [8], wherein the acid decomposable resin has a repeating unit derived from a monomer having a group that is decomposed by an action of an acid to generate a polar group,

the monomer all has a solubility index (R) of 2.0 to 5.0 (MPa)^{1/2}, the solubility index (R) being represented by a formula (1) and based on Hansen solubility parameters relative to the treatment liquid,

at least one of the monomer has a solubility index difference (ΔR) before and after acid leaving of 4.0 (MPa)^{1/2} or more,

$$R = {( 4 {( δ d 1 - δ d 2 )}^{2} + {( δ p 1 - δ p 2 )}^{2} + {( δ h 1 - δ h 2 )}^{2} )}^{1 / 2} \qquad Formula ( 1 )$$

δd1 represents a dispersion term in the Hansen solubility parameters of the monomer,

δp1 represents a polar term in the Hansen solubility parameters of the monomer,

δh1 represents a hydrogen-bonding term in the Hansen solubility parameters of the monomer,

δd2 represents a dispersion term in Hansen solubility parameters of the treatment liquid,

δp2 represents a polar term in the Hansen solubility parameters of the treatment liquid, and

δh2 represents a hydrogen-bonding term in the Hansen solubility parameters of the treatment liquid.

[10]

The method for testing a photosensitive composition according to any one of [1] to [9], wherein the content of the aromatic hydrocarbon relative to a total mass of the treatment liquid is 1 mass % or less.

[11]

A method for producing a photosensitive composition, the method including the method for testing a photosensitive composition according to any one of [1] to [10].

The present invention can provide a method for testing a photosensitive composition and a method for producing a photosensitive composition that can easily test whether or not the photosensitive composition exhibits a predetermined LWR.

### BRIEF DESCRIPTION OF THE DRAWINGS

FIG. 1 is a flow chart illustrating a first example of a method for testing a photosensitive composition according to an embodiment of the present invention;

FIG. 2 is a flow chart illustrating a first example of a method for obtaining reference data in the method for testing a photosensitive composition according to the embodiment of the present invention;

FIG. 3 is a flow chart illustrating a first example of a method for obtaining measurement data in the method for testing a photosensitive composition according to the embodiment of the present invention;

FIG. 4 is a flow chart illustrating a second example of the method for obtaining reference data in the method for testing a photosensitive composition according to the embodiment of the present invention;

FIG. 5 is a flow chart illustrating a second example of the method for obtaining measurement data in the method for testing a photosensitive composition according to the embodiment of the present invention;

FIG. 6 is a flow chart illustrating a second example of the method for testing a photosensitive composition according to the embodiment of the present invention; and

FIG. 7 is a flow chart illustrating an example of a method for producing a photosensitive composition according to an embodiment of the present invention.

### DESCRIPTION OF THE PREFERRED EMBODIMENTS

Hereinafter, a method for testing a photosensitive composition and a method for producing a photosensitive composition of the present invention will be described in detail on the basis of preferred embodiments illustrated in the attached drawings.

Note that the drawings described below are examples for describing the present invention, and the present invention is not limited to the drawings described below.

Note that, in the following description, numerical ranges described using “to” include numerical values described on both sides. For example, when & is a numerical value α to a numerical value β, the range of ϵ is a range including the numerical value α and the numerical value β, which is described using mathematical symbols as α≤ϵ≤β.

In addition, “the same” includes margin of error generally allowed in the corresponding technical field.

In this Specification, for the wording of groups (atomic groups), without departing from the spirit and scope of the present invention, wording without referring to substituted or unsubstituted encompasses groups not having a substituent and groups having a substituent. For example, “alkyl group” encompasses not only alkyl groups not having a substituent (unsubstituted alkyl groups), but also alkyl groups having a substituent (substituted alkyl groups). In this Specification, “organic group” refers to a group including at least one carbon atom.

Substituents are preferably monovalent substituents unless otherwise specified.

In this Specification, “actinic ray” or “radiation” means, for example, a line spectrum of a mercury lamp, far ultraviolet rays represented by excimer lasers, extreme ultraviolet rays (EUV light: Extreme Ultraviolet), X-rays, an electron beam (EB: Electron Beam), or the like. In this Specification, “light” means an actinic ray or a radiation.

In this Specification, “exposure” includes not only exposure using a line spectrum of a mercury lamp, far ultraviolet rays represented by excimer lasers, extreme ultraviolet rays (EUV light), X-rays, or the like, but also drawing using a corpuscular beam such as an electron beam or an ion beam, unless otherwise specified.

In this Specification, the bonding directions of divalent groups are not limited unless otherwise specified. For example, in a compound represented by a formula “X-Y-Z” where Y is —COO—, Y may be —CO—O— or —O—CO—. In other words, the compound may be “X—CO—O—Z” or “X—O—CO—Z”.

In this Specification, (meth)acrylate represents acrylate and methacrylate, and (meth)acrylic represents acrylic and methacrylic.

In this Specification, for resins, the weight-average molecular weight (Mw), the number-average molecular weight (Mn), and the dispersity (also referred to as molecular weight distribution) (Mw/Mn) are defined as polystyrene-equivalent values measured, using a GPC (Gel Permeation Chromatography) apparatus (HLC-8120GPC, manufactured by Tosoh Corporation), by GPC measurement (solvent: tetrahydrofuran, flow rate (sample injection amount): 10 μL, column: TSK gel Multipore HXL-M, manufactured by Tosoh Corporation, column temperature: 40° C., flow rate: 1.0 mL/min, detector: differential refractive index detector (Refractive Index Detector)).

In this Specification, the acid dissociation constant (pKa) represents pKa in an aqueous solution, specifically, a value determined using the following Software package 1, on the basis of the Hammett's substituent constant and the database of values in publicly known documents, by calculation. All the values of pKa described in this Specification are values determined by calculation using this software package.

Software package 1: Advanced Chemistry Development (ACD/Labs) Software V8.14 for Solaris (1994-2007 ACD/Labs).

Alternatively, pKa can be determined by a molecular orbital calculation method. Specifically, this method may be a calculation method of calculating H⁺ dissociation free energy in an aqueous solution based on a thermodynamic cycle. The H⁺ dissociation free energy can be calculated by a method such as DFT (density functional theory); however, the calculation method is not limited thereto and various other methods have been reported in documents and the like. Note that there are a plurality of pieces of software for performing DFT, such as Gaussian 16.

In this Specification, as described above, pKa refers to a value determined using Software package 1, on the basis of the Hammett's substituent constant and the database of values in publicly known documents, by calculation; however, when use of this method cannot determine pKa, a value determined on the basis of DFT (density functional theory) using Gaussian 16 is employed.

In this Specification, pKa refers to “pKa in an aqueous solution” as described above, but when pKa in an aqueous solution cannot be determined, “pKa in a dimethyl sulfoxide (DMSO) solution” is employed.

In this Specification, examples of the halogen atom include a fluorine atom, a chlorine atom, a bromine atom, and an iodine atom.

The inventors of the present invention have found the following: when a predetermined treatment liquid is used for two photosensitive compositions including components of the same types and predetermined reference data items of the dissolution rates of resist films are compared with each other, the photosensitive compositions can be determined as to whether or not the photosensitive compositions exhibit similar performances in terms of LWR performance.

Specifically, they have found the following: in the case of using a treatment liquid including an aliphatic hydrocarbon and having an aromatic hydrocarbon/metal impurity within a predetermined range, as described above, there is a correlation between the difference between the dissolution rates of resist films and the difference between LWRs. That is, they have found the following: when the dissolution rates of resist films are similar to each other, the LWR performances are also similar to each other; on the other hand, when the dissolution rates of resist films are different from each other, the LWR performances are also different from each other.

In the case of using an existing treatment liquid for two photosensitive compositions including components of the same types, the fluctuation width of the results of the dissolution rates of resist films is large and the fluctuation width of the results of LWR is also large.

By contrast, they have found the following: when a treatment liquid of the present invention is used for two photosensitive compositions including components of the same types, the fluctuation width of the results of the dissolution rates of resist films and the fluctuation width of the results of LWR are both small, and comparison between the results of the dissolution rates of resist films provides substantial coincidence with the LWR performances. Hereinafter, the method for testing a photosensitive composition will be specifically described.

### First Example of Method for Testing Photosensitive Composition

### First Example of Method for Obtaining Data

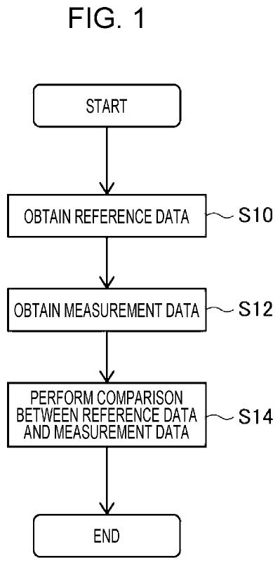

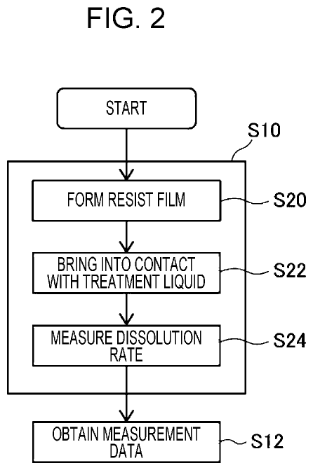

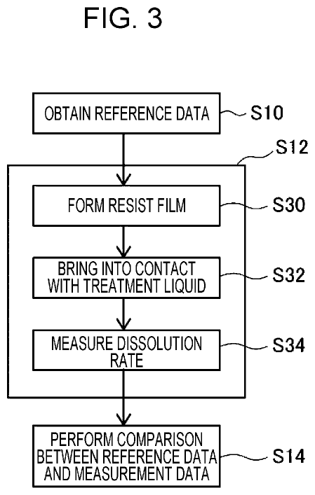

FIG. 1 is a flow chart illustrating a first example of a method for testing a photosensitive composition according to an embodiment of the present invention. FIG. 2 is a flow chart illustrating a first example of a method for obtaining reference data in the method for testing a photosensitive composition according to the embodiment of the present invention, and FIG. 3 is a flow chart illustrating a first example of a method for obtaining measurement data in the method for testing a photosensitive composition according to the embodiment of the present invention.

As illustrated in FIG. 1, the first example of the method for testing a photosensitive composition has a step 1 (Step S10) of obtaining reference data, a step 2 (Step S12) of obtaining measurement data, and a step 3 (Step S14) of performing comparison between the reference data and the measurement data to determine whether or not an allowable range is satisfied.

In the step 3 (Step S14), in a case where the allowable range is satisfied, the photosensitive composition is determined to exhibit a predetermined LWR.

On the other hand, in a case where, in the step 3 (Step S14), the allowable range is not satisfied, the photosensitive composition is determined not to exhibit the predetermined LWR.

In this way, the method for testing a photosensitive composition enables easy testing as to whether or not a photosensitive composition exhibits the predetermined LWR (Line Width Roughness).

The step 1 (Step S10) of obtaining the reference data has the following steps.

In the step 1 (Step S10) illustrated in FIG. 2, a reference photosensitive composition including a photoacid generator and an acid decomposable resin having a group that is decomposed by the action of an acid to generate a polar group is used to form a resist film on a substrate (Step S20).

The substrate is not particularly limited, and a semiconductor substrate such as a silicon substrate is used.

A method of forming the resist film is not particularly limited, and, for example, the resist film is formed using a spin coater. In the formation of the resist film, after the reference photosensitive composition is applied onto the substrate, the coating film of the reference photosensitive composition may be subjected to a pre-baking treatment.

Subsequently, the resist film on the substrate is brought into contact with a treatment liquid (Step S22). The method for bringing the resist film into contact with a treatment liquid is not particularly limited, and may be a method in which the treatment liquid is sprayed and applied to the resist film, or a method in which the resist film is immersed in the treatment liquid.

Note that various materials used in this step will be described later in detail.

Subsequently, the dissolution rate of the resist film is measured (Step S24) to obtain reference data (Step S10).

The dissolution rate of the resist film can be determined by dividing the amount of change in the resist film thickness by the time required for the treatment.

For example, when the resist film having been treated for a predetermined time still remains, the dissolution rate can be determined in the following manner: the film thicknesses before and after the treatment are measured to thereby determine the amount of change in film thickness, which is divided by the predetermined treatment time. The film thicknesseses before and after the treatment can be measured by, for example, an optical interference method or an ellipsometry method. Note that the film thickness before the treatment means the film thickness of the resist film before contact with the treatment liquid. Further, the film thickness after the treatment means the film thickness of the resist film after a predetermined time has elapsed from the contact with the treatment liquid.

On the other hand, when the resist film having been treated for a predetermined treatment time does not remain, the dissolution rate can be determined in the following manner: the film thickness before the treatment is divided by the time required for the treatment. The time required for the treatment can be determined, for example, from the behavior of a change in a parameter measured in real time by a spectral interference method or a quartz crystal microbalance method (QCM (Quartz crystal microbalance) method).

In the first example of the method for obtaining data (specifically, in a case where the resist film is unexposed), the reference data is preferably 1 to 1000 nm/s, more preferably 1 to 100 nm/s, and still more preferably 1 to 50 nm/s.

The step 2 (Step S12) of obtaining measurement data has the following steps.

In the step 2 (Step S12) illustrated in FIG. 3, a photosensitive composition for measurement including components of the same types as types of components included in the reference photosensitive composition is used to form a resist film on a substrate (Step S30).

The substrate is as described above in Step S20. The method of forming the resist film is as described above in Step S20.

Subsequently, the resist film on the substrate is brought into contact with the treatment liquid (Step S32). The resist film is brought into contact with the treatment liquid in the same manner as in Step S22 described above.

Subsequently, the dissolution rate of the resist film is measured (Step S34) to obtain the measurement data (Step S12). The dissolution rate of the resist film is measured in the same manner as in Step S24.

In order to perform comparison between the reference data and the measurement data in Step S14 (step 3), the reference data and the measurement data have the same data format. The same data format facilitates the comparison.

As described above, in Step S14 (step 3), the reference data and the measurement data are compared with each other, and whether or not the allowable range is satisfied is determined. The allowable range is appropriately set in accordance with, for example, the application.

The allowable range is defined by, for example, a ratio γ represented by (measurement data)/(reference data). The ratio γ is, for example, 0.9≤γ≤1.1.

Another example of the allowable range is a range of (reference data)±(given reference width set on the basis of past measurement results or the like).

### Second Example of Method for Obtaining Data

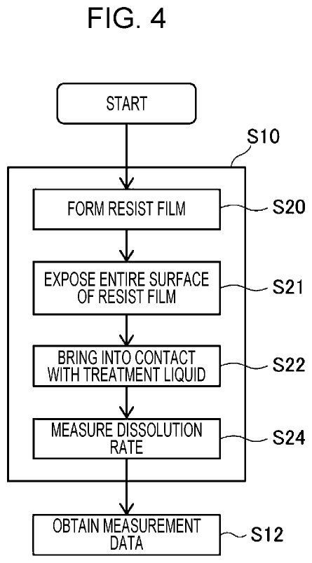

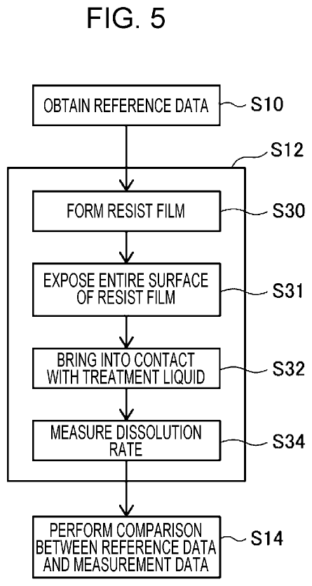

FIG. 4 is a flow chart illustrating a second example of the method for obtaining reference data in the method for testing a photosensitive composition according to the embodiment of the present invention, and FIG. 5 is a flow chart illustrating a second example of the method for obtaining measurement data in the method for testing a photosensitive composition according to the embodiment of the present invention.

Note that, in FIG. 4 and FIG. 5, detailed descriptions of the same steps as those in FIG. 2 and FIG. 3 will be omitted.

The second example of the method for obtaining the reference data and the second example of the method for obtaining the measurement data are different from the above-described first example of the method for obtaining the reference data and the above-described first example of the method for obtaining the measurement data, in that the entire surfaces of the resist films are exposed.

In the second example of the method for obtaining the reference data, as illustrated in FIG. 4, the resist film is formed (Step S20) and subsequently the entire surface of the resist film is exposed (Step S21). After Step S21, the exposed resist film is brought into contact with the treatment liquid (Step S22). Subsequently, the dissolution rate of the exposed resist film is measured (Step S24), to obtain reference data (Step S10).

In the second example of the method for obtaining measurement data, as illustrated in FIG. 5, the resist film is formed (Step S30) and subsequently the entire surface of the resist film is exposed (Step S31). After Step S31, the exposed resist film is brought into contact with the treatment liquid (Step S32). Subsequently, the dissolution rate of the exposed resist film is measured (Step S34), to obtain measurement data (Step S12).

In this way, the entire surfaces of the resist films can be exposed to obtain the reference data and the measurement data.

In the second example of the method for obtaining data, when the resist film is exposed, the reference data is preferably 1 to 10 nm/s, more preferably 0 to 5 nm/s, and still more preferably 0 to 1 nm/s.

In the exposure in Step S21 and Step S31, the exposure conditions are preferably the same conditions. The exposure is performed using light having a wavelength corresponding to the photosensitive compositions. For example, any one of a KrF excimer laser beam, an ArF excimer laser beam, an electron beam, and an extreme ultraviolet ray (EUV) is used.

When such a photosensitive composition is of a positive type, the exposed resist film is removed upon development. When the photosensitive composition is of a negative type, the exposed resist film remains upon development.

### Second Example of Method for Testing Photosensitive Composition

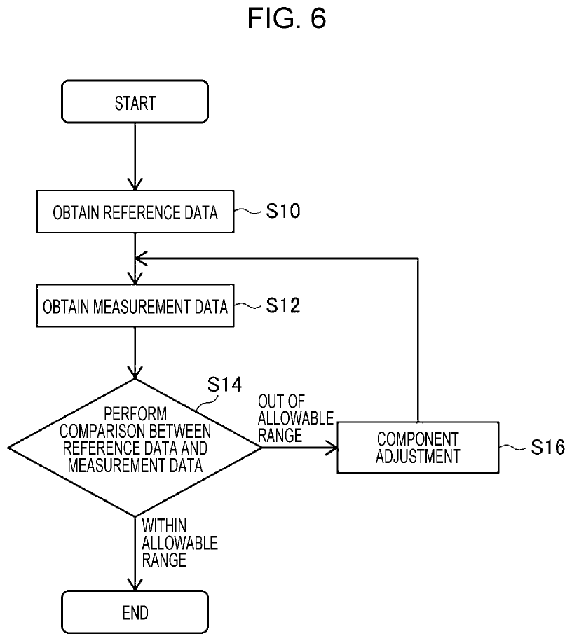

FIG. 6 is a flow chart illustrating a second example of the method for testing a photosensitive composition according to the embodiment of the present invention. Note that, in the second example of the method for testing a photosensitive composition illustrated in FIG. 6, detailed description of the same steps as the above-described steps of the first example of the method for testing a photosensitive composition will be omitted.

The second example of the method for testing a photosensitive composition is different from the above-described first example of the method for testing a photosensitive composition in that component adjustment of the photosensitive composition for measurement (Step S16) is performed when comparison between the reference data and the measurement data is performed and the measurement data is out of the allowable range in Step S14 (step 3).

On the other hand, in Step S14 (step 3), when the measurement data is within the allowable range, the component adjustment is not performed.

Note that, component adjustment of the photosensitive composition for measurement (Step S16) may be repeated such that the measurement data is within the allowable range in Step S14 (step 3).

The photosensitive composition for measurement includes the same components as components included in the reference photosensitive composition. In Step S16, in the case of performing component adjustment of the photosensitive composition for measurement, for example, the amount of at least one of the photoacid generator or the acid decomposable resin is adjusted. A component to be adjusted and the adjustment amount thereof in the component adjustment may be set in advance in accordance with the difference between the measurement data and the reference data and the degree of the difference between the measurement data and the reference data for, for example, in comparison of the measurement data with the reference data, a case where the measurement data is larger or a case where the measurement data is smaller.

### Example of Method for Producing Photosensitive Composition

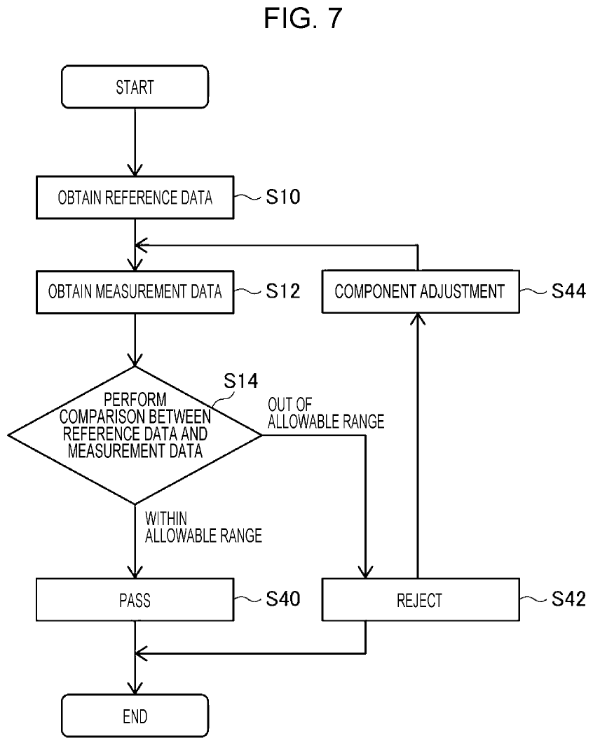

FIG. 7 is a flow chart illustrating an example of a method for producing a photosensitive composition according to an embodiment of the present invention. The above-described method for testing a photosensitive composition can be applied to the method for producing a photosensitive composition.

Note that, in the method for producing a photosensitive composition illustrated in FIG. 7, detailed description of the same steps as the above-described steps of the first example of the method for testing a photosensitive composition will be omitted.

The method for producing a photosensitive composition is different from the first example of the method for testing a photosensitive composition in the following points. The method for producing a photosensitive composition has, in a case where, in Step S14 (step 3), comparison between the reference data and the measurement data is performed and the measurement data is within the allowable range, a step of determining the photosensitive composition for measurement as an acceptable product (Step S40). Note that such an acceptable product is provided as a product of the photosensitive composition.

On the other hand, the method has, in a case where, in Step S14 (step 3), comparison between the reference data and the measurement data is performed and the measurement data is out of the allowable range, a step of determining the photosensitive composition for measurement as a rejected product (Step S42). Note that such a rejected product is not provided as a product.

In the method for producing a photosensitive composition, the photosensitive composition for measurement determined as a rejected product (Step S42) may be subjected to component adjustment of the photosensitive composition for measurement (Step S44).

The component adjustment of the photosensitive composition for measurement (Step S44) is the same as the above-described component adjustment of the photosensitive composition for measurement (Step S16) in the second example of the method for testing a photosensitive composition, and thus a detailed description thereof will be omitted. Also in the method for producing a photosensitive composition, the component adjustment of the photosensitive composition for measurement (Step S44) may be repeated such that the measurement data is determined to be within the allowable range.

In the above description, the comparison and the determination are performed by, for example, inputting various numerical values to a computer, performing comparison with an allowable range or the like, and performing determination on the basis of the allowable range or the like. Thus, the comparison and the determination are executed by, for example, a computer.

The present invention basically has the above-described features. The method for testing a photosensitive composition and the method for producing a photosensitive composition of the present invention have been described in detail so far; however, the present invention is not limited to the above-described embodiments, and various improvements or modifications may be clearly made without departing from the spirit and scope of the present invention. Hereinafter, the materials used in the above-described test method will be described in detail.

### Treatment Liquid

The treatment liquid includes an aromatic hydrocarbon, an organic solvent other than aromatic hydrocarbons, and a metal X, wherein the organic solvent includes an aliphatic hydrocarbon, the metal X is at least one metal selected from the group consisting of Al, Fe, and Ni, and the mass ratio of the content of the aromatic hydrocarbon to the content of the metal X is 5.0×10⁴ to 2.0×10¹⁰.

Hereinafter, components included in the treatment liquid will be described in detail.

### Aromatic Hydrocarbon

The treatment liquid includes an aromatic hydrocarbon.

The “aromatic hydrocarbon” means a hydrocarbon composed only of hydrogen atoms and carbon atoms and having an aromatic ring. Aromatic hydrocarbons are not included in the organic solvents.

The content of the aromatic hydrocarbon relative to the total mass of the treatment liquid is preferably 1 mass % or less, more preferably 1 to 10000 mass ppm, still more preferably 5 to 10000 mass ppm, and particularly preferably 50 to 10000 mass ppm. Note that, when the aromatic hydrocarbon includes two or more aromatic hydrocarbons, the total content of the two or more aromatic hydrocarbons is preferably in such a range.

The number of carbon atoms of the aromatic hydrocarbon is preferably 6 to 30, more preferably 6 to 20, and still more preferably 10 to 12.

The aromatic hydrocarbon has an aromatic ring that may be monocyclic or polycyclic.

The aromatic hydrocarbon has an aromatic ring in which the number of ring members is preferably 6 to 12, more preferably 6 to 8, and still more preferably 6.

The aromatic hydrocarbon has an aromatic ring that may further have a substituent. Examples of the substituent include an alkyl group, an alkenyl group, and a group that is a combination of the foregoing. The alkyl group and the alkenyl group may be linear, branched, or cyclic. For the alkyl group and the alkenyl group, the number of carbon atoms is preferably 1 to 10, and more preferably 1 to 5.

Examples of the aromatic ring in the aromatic hydrocarbon include a benzene ring that may have a substituent, a naphthalene ring that may have a substituent, and an anthracene ring that may have a substituent, and preferred is a benzene ring that may have a substituent.

In other words, the aromatic hydrocarbon is preferably benzene that may have a substituent.

The aromatic hydrocarbon preferably includes at least one selected from the group consisting of C₁₀H₁₄, C₁₁H₁₆, and C₁₀H₁₂.

The aromatic hydrocarbon is also preferably a compound represented by a formula (c).

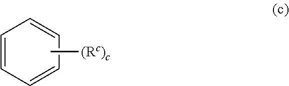

In the formula (c), R^{c} represents a substituent. c represents an integer of 0 to 6.

R^{c} represents a substituent.

The substituent represented by R^{c} is preferably an alkyl group or an alkenyl group.

The alkyl group and the alkenyl group may be linear, branched, or cyclic.

For the alkyl group and the alkenyl group, the number of carbon atoms is preferably 1 to 10, and more preferably 1 to 5.

When a plurality of R^{c}'s are present, R_{c}'s may be the same or different, and R^{c}'s may be bonded together to form a ring.

R^{c} (when a plurality of R^{c}'s are present, a part or all of the plurality of R^{c}'s) and the benzene ring in the formula (c) may be fused to form a fused ring.

c represents an integer of 0 to 6.

c is preferably an integer of 1 to 5, and more preferably an integer of 1 to 4.

The aromatic hydrocarbon preferably has a molecular weight of 50 or more, more preferably 100 or more, and still more preferably 120 or more. The upper limit is preferably 1000 or less, more preferably 300 or less, and still more preferably 150 or less.

Examples of the aromatic hydrocarbon include C₁₀H₁₄ such as 1,2,4,5-tetramethyl-benzene, 1-ethyl-3,5-dimethyl-benzene, 1,2,3,5-tetramethyl-benzene, and 1-ethyl-2,4-dimethyl-benzene; C₁₁H₁₆ such as 1-methyl-4-(1-methylpropyl)-benzene and (1-methybutyl)-benzene; and C₁₀H₁₂ such as 1-methyl-2-(2-propenyl)-benzene and 1,2,3,4-tetrahydro-naphthalene.

The aromatic hydrocarbon is preferably 1,2,4,5-tetramethyl-benzene, 1-ethyl-3,5-dimethyl-benzene, 1,2,3,5-tetramethyl-benzene, 1-methyl-4-(1-methylpropyl)-benzene, and C₁₀H₁₂, and more preferably 1-ethyl-3,5-dimethyl-benzene or 1,2,3,5-tetramethyl-benzene.

Such aromatic hydrocarbons may be used alone or in combination of two or more thereof.

The treatment liquid preferably includes two or more aromatic hydrocarbons, more preferably includes three or more aromatic hydrocarbons, still more preferably includes three to eight aromatic hydrocarbons, yet more preferably includes three to four aromatic hydrocarbons, and particularly preferably includes three aromatic hydrocarbons.

Examples of the method for measuring the aromatic hydrocarbon content include methods for measuring the organic solvent content described later.

Examples of the method for adjusting the aromatic hydrocarbon content include a method in which raw materials having a low aromatic hydrocarbon content are selected as raw materials for constituting various components, a method in which distillation is performed under conditions in which contamination is suppressed by, for example, lining the inside of an apparatus with TEFLON (registered trademark), and a method of adding an aromatic hydrocarbon.

### Organic Solvent

The treatment liquid includes an organic solvent other than the above-described aromatic hydrocarbon. In other words, in this Specification, aromatic hydrocarbons are not included in the above-described organic solvent.

### Aliphatic Hydrocarbon

The organic solvent includes an aliphatic hydrocarbon.

The “aliphatic hydrocarbon” means a hydrocarbon composed only of hydrogen atoms and carbon atoms and having no aromatic ring.

The aliphatic hydrocarbon may be linear, branched, or cyclic (monocyclic or polycyclic), and is preferably linear. The aliphatic hydrocarbon may be a saturated aliphatic hydrocarbon or an unsaturated aliphatic hydrocarbon.

The number of carbon atoms of the aliphatic hydrocarbon is often 2 or more, preferably 5 or more, and more preferably 10 or more. The upper limit is preferably 30 or less, more preferably 20 or less, still more preferably 15 or less, and particularly preferably 13 or less. Specifically, the number of carbon atoms of the aliphatic hydrocarbon is preferably 11.

Examples of the aliphatic hydrocarbon include pentane, isopentane, hexane, isohexane, cyclohexane, ethylcyclohexane, methylcyclohexane, heptane, octane, isooctane, nonane, decane, methyldecane, undecane, dodecane, tridecane, tetradecane, pentadecane, hexadecane, heptadecane, 2,2,4-trimethylpentane, and 2,2,3-trimethylhexane.

The aliphatic hydrocarbon preferably includes an aliphatic hydrocarbon having 5 or more carbon atoms (preferably 20 or less carbon atoms), more preferably includes an aliphatic hydrocarbon having 10 or more carbon atoms (preferably 13 or less carbon atoms), still more preferably includes at least one selected from the group consisting of decane, undecane, dodecane, and methyldecane, and particularly preferably includes undecane.

The content of the aliphatic hydrocarbon relative to the total mass of the treatment liquid is preferably 0.8 mass % or more and less than 100 mass %, more preferably 1 to 50 mass %, still more preferably 3 to 30 mass %, and particularly preferably 8 to 18 mass %.

The content of the aliphatic hydrocarbon relative to the total mass of the organic solvent is preferably 0.8 mass % or more and 100 mass % or less, more preferably 1 to 100 mass %, still more preferably 2 to 100 mass %, yet more preferably 2 to 50 mass %, particularly preferably 3 to 30 mass %, and most preferably 8 to 18 mass %.

### Ester-Based Solvent

The organic solvent preferably further includes an ester-based solvent.

The ester-based solvent may be linear, branched, or cyclic (monocyclic or polycyclic), and is preferably linear.

The number of carbon atoms of the ester-based solvent is often 2 or more, preferably 3 or more, more preferably 4 or more, and still more preferably 6 or more. The upper limit is often 20 or less, preferably 10 or less, more preferably 8 or less, and particularly preferably 7 or less. Specifically, the number of carbon atoms of the ester-based is preferably 6.

Examples of ester-based solvent include butyl acetate, isobutyl acetate, tert-butyl acetate, methyl acetate, ethyl acetate, propyl acetate, isopropyl acetate, hexyl acetate, methoxybutyl acetate, amyl acetate, isoamyl acetate, methyl formate, ethyl formate, butyl formate, propyl formate, amyl formate, isoamyl formate, methyl lactate, ethyl lactate, butyl lactate, propyl lactate, methyl 2-hydroxyisobutyrate, ethyl butyrate, ethyl isobutyrate, ethyl propionate, propyl propionate, isopropyl propionate, butyl propionate, and isobutyl propionate.

The ester-based solvent preferably includes at least one selected from the group consisting of butyl acetate, isobutyl acetate, amyl formate, ethyl acetate, and hexyl acetate, more preferably includes at least one selected from the group consisting of butyl acetate, isobutyl acetate, ethyl acetate, and hexyl acetate, and still more preferably includes butyl acetate.

The content of the ester-based solvent relative to the total mass of the treatment liquid is preferably 10 mass % or more and less than 100 mass %, more preferably 60 to 99 mass %, still more preferably 60 to 95 mass %, and particularly preferably 80 to 90 mass %.

The content of the ester-based solvent relative to the total mass of the organic solvent is preferably 10 mass % or more and less than 100 mass %, more preferably 60 to 99 mass %, still more preferably 60 to 95 mass %, and particularly preferably 80 to 90 mass %.

The organic solvent preferably includes an aliphatic hydrocarbon and an ester-based solvent, and more preferably composed only of an aliphatic hydrocarbon and an ester-based solvent. It more preferably includes, as an aliphatic hydrocarbon, at least one selected from the group consisting of undecane, dodecane, and decane, and includes, as an ester-based solvent, at least one selected from the group consisting of butyl acetate, isobutyl acetate, amyl formate, ethyl acetate, and hexyl acetate. In particular, the organic solvent is particularly preferably composed only of undecane and butyl acetate.

When the organic solvent includes an aliphatic hydrocarbon and an ester-based solvent, the ratio of the content of the ester-based solvent to the content of the aliphatic hydrocarbon (content of ester-based solvent/content of aliphatic hydrocarbon) is preferably 65/35 to 99/1, more preferably 85/15 to 95/5, and still more preferably 90/10.

The total content of the aliphatic hydrocarbon and the ester-based solvent relative to the total mass of the treatment liquid is preferably 10 mass % or more and less than 100 mass %, more preferably 80 mass % or more and less than 100 mass %, and still more preferably 95 mass % or more and less than 100 mass %.

The total content of the aliphatic hydrocarbon and the ester-based solvent relative to the total mass of the organic solvent is preferably 10 to 100 mass %, more preferably 80 to 100 mass %, still more preferably 95 to 100 mass %, and particularly preferably 99 to 100 mass %.

### Another Solvent

The organic solvent may include, in addition to those described above, another solvent.

Examples of the other solvent include a ketone-based solvent, an amide-based solvent, and an ether-based solvent.

Organic solvents may be used alone or in combination of two or more thereof.

The content of such an organic solvent relative to the total mass of the treatment liquid is preferably 90 mass % or more, more preferably 95 mass % or more, and still more preferably 98 mass % or more. The upper limit relative to the total mass of the treatment liquid is often less than 100 mass %.

Examples of a method for measuring the content of the organic solvent include a method using GC (gas chromatography) and a method using GC-MS (gas chromatography-mass spectrometry).

### Metal X

The treatment liquid includes a metal X.

The metal X is at least one metal selected from the group consisting of Al, Fe, and Ni. The treatment liquid preferably includes all the metals of Al, Fe, and Ni.

The metal X may be present, in the treatment liquid, in an ionic state or may be present at zero valence. When it is present at zero valence, it may be present in the form of particles. Such metals X may be used alone or in combination of two or more thereof.

The content of the metal X is, relative to the total mass of the treatment liquid, preferably 0.01 to 3000 mass ppt, more preferably 0.1 to 2500 mass ppt, and still more preferably 0.1 to 2000 mass ppt. Note that when the treatment liquid includes two or more metals, the total content of the two or more metals is preferably in such a range.

The content of at least one of Al, Fe, or Ni in the metal X relative to the total mass of the treatment liquid is preferably 0.1 to 2000 mass ppt.

The mass ratio of the aromatic hydrocarbon content to the metal X content (aromatic hydrocarbon content/metal X content) is 5.0×10⁴ to 2.0×10¹⁰, preferably 3.0×10⁵ to 1.0×10⁹, and more preferably 3.0×10⁵ to 2.5×10⁸.

Examples of the method for measuring the metal X content include publicly known measurement methods such as ICP-MS (ICP mass spectrometry).

Examples of the method for adjusting the metal X content include a method of performing filtration using the filter, a method of selecting raw materials having a low content of the metal X as raw materials for constituting various components, a method of performing distillation under conditions in which contamination is suppressed by, for example, lining the inside of an apparatus with TEFLON (registered trademark), and a method of adding a metal X or a compound including a metal X.

### Reference Photosensitive Composition and Photosensitive Composition for Measurement

The reference photosensitive composition includes an acid decomposable resin having a group that is decomposed by the action of an acid to generate a polar group, and a photoacid generator.

The photosensitive composition for measurement and the above-described reference photosensitive composition include components of the same types. The phrase “include components of the same types” means including such components having the same structure, and the contents thereof may be different. Note that, for resins including repeating units, as long as the species constituting the repeating units are the same, the contents of the repeating units may be different.

More specifically, for the acid decomposable resin, as long as the species of the repeating units in the acid decomposable resin included in the reference photosensitive composition are the same as the species of the repeating units in the acid decomposable resin included in the photosensitive composition for measurement, the contents of the repeating units in the acid decomposable resin included in the reference photosensitive composition and the contents of the repeating units in the acid decomposable resin included in the photosensitive composition for measurement may be different from each other. The content of the acid decomposable resin included in the reference photosensitive composition may be different from the content in the acid decomposable resin included in the photosensitive composition for measurement.

For the photoacid generator, as long as the photoacid generator included in the reference photosensitive composition and the photoacid generator included in the photosensitive composition for measurement are compounds having the same structure, the content of the photoacid generator included in the reference photosensitive composition and the content of the photoacid generator included in the photosensitive composition for measurement may be different from each other. Thus, for example, when the reference photosensitive composition includes a photoacid generator X and an acid decomposable resin including a specified repeating unit A and a specified repeating unit B, the photosensitive composition for measurement also includes the photoacid generator X and an acid decomposable resin including the specified repeating unit A and the specified repeating unit B.

Further, when the reference photosensitive composition includes another component other than the photoacid generator and the acid decomposable resin, the photosensitive composition for measurement also includes another component of the same kind (for example, an acid diffusion control agent). For example, when the reference photosensitive composition includes an acid diffusion control agent Z, the photosensitive composition for measurement also includes an acid diffusion control agent Z having the same structure as the acid diffusion control agent Z included in the reference photosensitive composition, and the contents thereof may be different. Note that, in the case of using a resin including a repeating unit as the other component, as in the above-described acid decomposable resin, as long as the species of the repeating unit of the resin included in the reference photosensitive composition and the species of the repeating unit of the resin included in the photosensitive composition for measurement are the same, the contents of the repeating units and the contents of the resins may be different.

Note that, the photosensitive composition for measurement is often a composition produced at a different time from the reference photosensitive composition, that is, a composition produced in a different lot.

Hereinafter, the components will be described in detail.

### Acid Decomposable Resin Having Group that is Decomposed by Action of Acid to Generate Polar Group

The reference photosensitive composition includes an acid decomposable resin (hereinafter, also simply referred to as “resin (A)”) having a group that is decomposed by the action of an acid to generate a polar group (hereinafter, also simply referred to as “acid decomposable group”).

The acid decomposable resin will be described later in detail; in one of preferred embodiments of the acid decomposable resin, the acid decomposable resin has a repeating unit derived from a monomer having a group that is decomposed by the action of an acid to generate a polar group, the monomer all has a solubility index (R) of 2.0 to 5.0 (MPa)^{1/2}, the solubility index (R) being represented by a formula (1) described later and based on Hansen solubility parameters for a treatment liquid, and at least one of the monomer has a difference (ΔR) between the solubility indexes (R) before and after acid leaving of 4.0 (MPa)^{1/2} or more.

Hereinafter, first, such properties will be described.

In order to identify resins including desired properties, for example, Hansen solubility parameters (Hansen solubility parameters) can be used.

The Hansen solubility parameters are provided by dividing the solubility of a substance into three components (dispersion term δd, polar term δp, and hydrogen-bonding term δh) and expressing the components in a three-dimensional space. The dispersion term δd represents the effect of dispersion force, the polarity term δp represents the effect of dipole-dipole force, and the hydrogen-bonding term δh represents the effect of hydrogen-bonding force.

The definition and calculation of the Hansen solubility parameters are described in Charles M. Hansen, Hansen Solubility Parameters: A Users Handbook (CRC Press, 2007). A computer software Hansen Solubility Parameters in Practice (HSPiP) can be used to thereby easily estimate the Hansen solubility parameters, even for a compound whose literature value or the like is not known, from its chemical structure. In the present invention, HSPiP version 4.1 is used and estimated values are used to thereby determine the dispersion term δd, the polar term δp, and the hydrogen-bonding term δh of monomers. For the solvents and monomers registered in the database, their values are used.

In general, the Hansen solubility parameters of a monomer constituting a specified resin can be determined by a solubility test in which a sample of the monomer constituting the resin is dissolved in a large number of different solvents having determined Hansen solubility parameters to measure the solubility. Specifically, among the solvents used in the solubility test, a sphere (solubility sphere) is found such that all the three-dimensional points of solvents having dissolved a monomer constituting the resin are included in the sphere, but the points of solvents not having dissolved the monomer are positioned outside the sphere; and the center coordinates of the sphere are defined as the Hansen solubility parameters of the monomer constituting the resin.

For example, when the Hansen solubility parameters of another solvent that has not been used in the measurement of the Hansen solubility parameters of the monomer constituting the resin are (δd, δp, δh), and the point indicated by the coordinates is included inside the solubility sphere of the monomer constituting the resin, the solvent inferentially dissolves the monomer constituting the resin. On the other hand, when the coordinate point is outside the solubility sphere of the monomer constituting the resin, the solvent inferentially cannot dissolve the monomer constituting the resin.

In the present invention, the above-described Hansen solubility parameters are used and the treatment liquid is used as the reference; in other words, the coordinates of the Hansen solubility parameters of the treatment liquid are used as the reference and a structural unit (or a monomer) positioned at a certain distance from the reference is determined to be appropriately dissolved in the treatment liquid; a resin (A) constituted by such a structural unit can be used.

Specifically, for the Hansen solubility parameters of the treatment liquid, the dispersion term is defined as δd2 (MPa)^{1/2}, the polarity term is defined as δp2 (MPa)^{1/2}, and the hydrogen-bonding term is defined as δh2 (MPa)^{1/2}; the solubility parameter distance R, from the treatment liquid, based on the Hansen solubility parameters and represented by a formula (1), is defined as the solubility index of each monomer from which a structural unit constituting the resin is derived (hereinafter, may be referred to as solubility index (R)).

$$R = {( 4 {( δ d - 1 δ d 2 )}^{2} + {( δ p 1 - δ p 2 )}^{2} + {( δ h 1 - δ h 2 )}^{2} )}^{1 / 2} \qquad Formula ( 1 )$$

δd1 represents the dispersion term in the Hansen solubility parameters of the monomer.

δp1 represents the polar term in the Hansen solubility parameters of the monomer.

δh1 represents the hydrogen-bonding term in the Hansen solubility parameters of the monomer.

δd2 represents the dispersion term in the Hansen solubility parameters of the treatment liquid.

δp2 represents the polar term in the Hansen solubility parameters of the treatment liquid.

δh2 represents the hydrogen-bonding term in the Hansen solubility parameters of the treatment liquid.

Note that δd2, δ2, or δh2 of the treatment liquid is determined in the following manner: δd2, δp2, or δh2 of the solvent components (for example, an aromatic hydrocarbon and an organic solvent) included in the treatment liquid are multiplied by the contents of the solvent components and the products are added up to provide a numerical value.

In the resin (A), the monomer having a group that is decomposed by the action of an acid to generate a polar group all preferably has a solubility index (R) of 2.0 to 5.0 (MPa)^{1/2}, more preferably 3.1 to 4.9 (MPa)^{1/2}, and still more preferably 3.2 to 4.9 (MPa)^{1/2}.

At least one structural unit species included in the resin (A) is preferably a structural unit derived from a monomer having a difference between the solubility indexes (R) before and after acid leaving (solubility index difference (ΔR)) of 4.0 (MPa)^{1/2} or more, and having a group that is decomposed by the action of an acid to generate a polar group.

The upper limit of ΔR above is not particularly limited, but is often 10 (MPa)^{1/2} or less.

Hereinafter, the repeating unit included in the acid decomposable resin will be described in detail.

### Repeating Unit (A-a) Having Acid Decomposable Group

The resin (A) preferably has a repeating unit (A-a) having a group that is decomposed by the action of an acid to generate a polar group (hereinafter, also referred to as “repeating unit (A-a)”).

The acid decomposable group is a group that is decomposed by the action of an acid to generate a polar group, and preferably has a structure in which the polar group is protected with a leaving group that leaves by the action of an acid. The resin having the repeating unit (A-a) is subjected to the action of an acid to provide increased polarity, to thereby provide an increased degree of solubility in an alkali developer and a decreased degree of solubility in an organic solvent.

The polar group is preferably an alkali-soluble group, and examples thereof include acidic groups such as a carboxyl group, a phenolic hydroxyl group, fluorinated alcohol groups, a sulfonic group, a sulfonamide group, a sulfonylimide group, (alkylsulfonyl)(alkylcarbonyl) methylene groups, (alkylsulfonyl)(alkylcarbonyl) imide groups, bis(alkylcarbonyl) methylene groups, bis(alkylcarbonyl) imide groups, bis(alkylsulfonyl) methylene groups, bis(alkylsulfonyl) imide groups, and tris(alkylcarbonyl) methylene groups, and tris (alkylsulfonyl) methylene groups, and an alcoholic hydroxyl group.

In particular, the polar group is preferably a carboxyl group, a phenolic hydroxy group, a fluorinated alcohol group (preferably a hexafluoroisopropanol group), or a sulfonic group.

Examples of the leaving group that leaves by the action of an acid include groups represented by formulas (Y1) to (Y4).

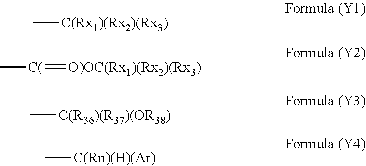

In the formula (Y1) and the formula (Y2), Rx₁ to Rx₃ each independently represent an alkyl group (linear or branched), a cycloalkyl group (monocyclic or polycyclic), an alkenyl group (linear or branched), or an aryl group (monocyclic or polycyclic). Note that, when all of Rx₁ to Rx₃ are alkyl groups (linear or branched), at least two among Rx₁ to Rx₃ are preferably methyl groups.

In particular, preferably, Rx₁ to Rx₃ each independently represent a linear or branched alkyl group, and more preferably Rx₁ to Rx₃ each independently represent a linear alkyl group.

Two among Rx₁ to Rx₃ may be bonded together to form a monocyclic ring or a polycyclic ring.

For Rx₁ to Rx₃, the alkyl group is preferably an alkyl group having 1 to 5 carbon atoms such as a methyl group, an ethyl group, an n-propyl group, an isopropyl group, an n-butyl group, an isobutyl group, or a t-butyl group.

For Rx₁ to Rx₃, the cycloalkyl group is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

For Rx₁ to Rx₃, the aryl group is preferably an aryl group having 6 to 10 carbon atoms, and examples thereof include a phenyl group, a naphthyl group, and an anthryl group.

For Rx₁ to Rx₃, the alkenyl group is preferably a vinyl group.

The ring formed by bonding together two among Rx₁ to Rx₃ is preferably a cycloalkyl group. The cycloalkyl group formed by bonding together two among Rx₁ to Rx₃ is preferably a monocyclic cycloalkyl group such as a cyclopentyl group or a cyclohexyl group, and a polycyclic cycloalkyl group such as a norbornyl group, a tetracyclodecanyl group, a tetracyclododecanyl group, or an adamantyl group, and more preferably a monocyclic cycloalkyl group having 5 to 6 carbon atoms.

In the cycloalkyl group formed by bonding together two among Rx₁ to Rx₃, for example, one of the methylene groups constituting the ring may be replaced by a heteroatom such as an oxygen atom, a group having a heteroatom such as a carbonyl group, or a vinylidene group. In the cycloalkyl group, one or more of the ethylene groups constituting the cycloalkane ring may be replaced by vinylene groups.

In a preferred embodiment, for the group represented by the formula (Y1) or the formula (Y2), for example, Rx₁ is a methyl group or an ethyl group, and Rx₂ and Rx₃ are bonded together to form the above-described cycloalkyl group.

When the reference photosensitive composition and the photosensitive composition for measurement are, for example, resist compositions for EUV exposure, the alkyl groups, cycloalkyl groups, alkenyl groups, or aryl groups represented by Rx₁ to Rx₃ and a ring formed by bonding together two among Rx₁ to Rx₃ also preferably further have a fluorine atom or an iodine atom as a substituent.

In the formula (Y3), R₃₆ to R₃₈ each independently represent a hydrogen atom or a monovalent organic group. R₃₇ and R₃₈ may be bonded together to form a ring. Examples of the monovalent organic group include alkyl groups, cycloalkyl groups, aryl groups, aralkyl groups, and alkenyl groups. R₃₆ is also preferably a hydrogen atom.

Note that the alkyl groups, cycloalkyl groups, aryl groups, and aralkyl groups may include a heteroatom such as an oxygen atom and/or a group having a heteroatom such as a carbonyl group. For example, in the alkyl groups, cycloalkyl groups, aryl groups, and aralkyl groups, for example, one or more methylene groups may be replaced by a heteroatom such as an oxygen atom and/or a group having a heteroatom such as a carbonyl group.

In a repeating unit having an acid decomposable group described later, R₃₈ and another substituent in the main chain of the repeating unit may be bonded together to form a ring. The group formed by bonding together R₃₈ and another substituent in the main chain of the repeating unit is preferably an alkylene group such as a methylene group.

When the reference photosensitive composition and the photosensitive composition for measurement are, for example, resist compositions for EUV exposure, the monovalent organic groups represented by R₃₆ to R₃₈ and the ring formed by bonding together R₃₇ and R₃₈ also preferably further have a fluorine atom or an iodine atom as a substituent.

The formula (Y3) is preferably a group represented by the following formula (Y3-1).

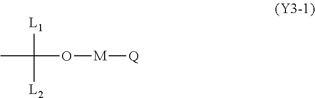

L₁ and L₂ each independently represent a hydrogen atom, an alkyl group, a cycloalkyl group, an aryl group, or a group that is a combination of the foregoing (for example, a group that is a combination of an alkyl group and an aryl group).

M represents a single bond or a divalent linking group.

Q represents an alkyl group that may include a heteroatom, a cycloalkyl group that may include a heteroatom, an aryl group that may include a heteroatom, an amino group, an ammonium group, a mercapto group, a cyano group, an aldehyde group, or a group that is a combination of the foregoing (for example, a group that is a combination of an alkyl group and a cycloalkyl group).

In the alkyl group and the cycloalkyl group, for example, one of methylene groups may be replaced by a heteroatom such as an oxygen atom or a group having a heteroatom such as a carbonyl group.

Note that one of L₁ and L₂ is preferably a hydrogen atom and the other is preferably an alkyl group, a cycloalkyl group, an aryl group, or a group that is a combination of an alkylene group and an aryl group.

At least two among Q, M, and L₁ may be bonded together to form a ring (preferably a 5-membered or 6-membered ring).

From the viewpoint of reducing the size of patterns, L₂ is preferably a secondary or tertiary alkyl group, and more preferably a tertiary alkyl group. Examples of the secondary alkyl group include an isopropyl group, a cyclohexyl group, and a norbornyl group, and examples of the tertiary alkyl group include a tert-butyl group and an adamantane group.

When the reference photosensitive composition and the photosensitive composition for measurement are, for example, resist compositions for EUV exposure, the alkyl groups, cycloalkyl groups, aryl groups, and groups that are combinations of the foregoing represented by L₁ and L₂ also preferably further have a fluorine atom or an iodine atom as a substituent. In addition to the fluorine atom and the iodine atom, the alkyl groups, the cycloalkyl groups, the aryl groups, and the aralkyl groups also preferably include a heteroatom such as an oxygen atom (in other words, in the alkyl groups, the cycloalkyl groups, the aryl groups, and the aralkyl groups, for example, one methylene group is replaced by a heteroatom such as an oxygen atom or a group having a heteroatom such as a carbonyl group).

When the reference photosensitive composition and the photosensitive composition for measurement are, for example, resist compositions for EUV exposure, in the groups represented by Q that are the alkyl group that may include a heteroatom, the cycloalkyl group that may include a heteroatom, the aryl group that may include a heteroatom, the amino group, the ammonium group, the mercapto group, the cyano group, the aldehyde group, and the groups that are combinations of the foregoing, such heteroatoms are also preferably heteroatoms selected from the group consisting of a fluorine atom, an iodine atom, and an oxygen atom.

In the formula (Y4), Ar represents an aromatic ring group. Rn represents an alkyl group, a cycloalkyl group, or an aryl group. Rn and Ar may be bonded together to form a non-aromatic ring. Ar is more preferably an aryl group.

When the reference photosensitive composition and the photosensitive composition for measurement are, for example, resist compositions for EUV exposure, the aromatic ring group represented by Ar and the alkyl group, the cycloalkyl group, and the aryl group represented by Rn also preferably have a fluorine atom and an iodine atom as substituents.

In the case where, in the leaving group for protecting the polar group, a non-aromatic ring is directly bonded to the polar group (or a residue thereof), from the viewpoint of further improving acid decomposability, a ring member atom adjacent to the ring member atom directly bonded to the polar group (or a residue thereof) in the non-aromatic ring also preferably does not have a halogen atom such as a fluorine atom as a substituent.

Other examples of the leaving group that leaves by the action of an acid include 2-cyclopentenyl groups having substituents (such as alkyl groups), such as a 3-methyl-2-cyclopentenyl group, and cyclohexyl groups having substituents (such as alkyl groups), such as a 1,1,4,4-tetramethylcyclohexyl group.

The repeating unit (A-a) is also preferably a repeating unit represented by a formula (A).

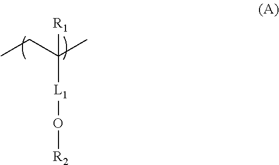

L₁ represents a divalent linking group that may have a fluorine atom or an iodine atom; R₁ represents a hydrogen atom, a fluorine atom, an iodine atom, an alkyl group that may have a fluorine atom or an iodine atom, or an aryl group that may have a fluorine atom or an iodine atom; R₂ represents a leaving group that leaves by the action of an acid and that may have a fluorine atom or an iodine atom.

Note that, in a preferred embodiment of the repeating unit represented by the formula (A), at least one of L₁, R₁, or R₂ has a fluorine atom or an iodine atom.

L₁ represents a divalent linking group that may have a fluorine atom or an iodine atom. Examples of the divalent linking group that may have a fluorine atom or an iodine atom include —CO—, —O—, —S—, —SO—, —SO₂—, a hydrocarbon group that may have a fluorine atom or an iodine atom (for example, an alkylene group, a cycloalkylene group, an alkenylene group, or an arylene group), and a linking group in which a plurality of the foregoing are linked together. Of these, L₁ is preferably —CO—, an arylene group, or an -arylene group-alkylene group that may have a fluorine atom or an iodine atom-, and more preferably —CO—, an arylene group, or an -arylene group-alkylene group that may have a fluorine atom or an iodine atom-.

The arylene group is preferably a phenylene group.

The alkylene group may be linear or branched. The number of carbon atoms of the alkylene group is not particularly limited, but is preferably 1 to 10, more preferably 1 to 3.

When the alkylene group has a fluorine atom or an iodine atom, the total number of fluorine atoms and iodine atoms included in the alkylene group is not particularly limited, but is preferably 2 or more, more preferably 2 to 10, and still more preferably 3 to 6.

R₁ represents a hydrogen atom, a fluorine atom, an iodine atom, an alkyl group that may have a fluorine atom or an iodine atom, or an aryl group that may have a fluorine atom or an iodine atom.

The alkyl group may be linear or branched. The number of carbon atoms of the alkyl group is not particularly limited, but is preferably 1 to 10, and more preferably 1 to 3.

The total number of fluorine atoms and iodine atoms included in the alkyl group having a fluorine atom or an iodine atom is not particularly limited, but is preferably 1 or more, more preferably 1 to 5, and still more preferably 1 to 3.

The alkyl group may include a heteroatom other than halogen atoms, such as an oxygen atom.

R₂ represents a leaving group that leaves by the action of an acid and that may have a fluorine atom or an iodine atom. Examples of the leaving group that may have a fluorine atom or an iodine atom include the above-described leaving groups represented by the formulas (Y1) to (Y4) and having a fluorine atom or an iodine atom, and preferred examples thereof are also the same.

The repeating unit (A-a) is also preferably a repeating unit represented by a general formula (AI).

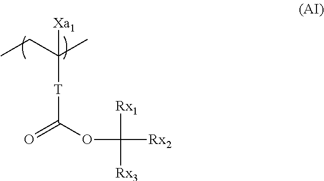

In the general formula (AI),

Xa₁ represents a hydrogen atom or an alkyl group that may have a substituent.

T represents a single bond or a divalent linking group.

Rx₁ to Rx₃ each independently represent an alkyl group (linear or branched), a cycloalkyl group (monocyclic or polycyclic), an aryl group, or an alkenyl group. Note that, when Rx₁ to Rx₃ are all alkyl groups (linear or branched), at least two among Rx₁ to Rx₃ are preferably methyl groups.

Two among Rx₁ to Rx₃ may be bonded together to form a cycloalkyl group (monocyclic or polycyclic).

The alkyl group that is represented by Xa₁ and may have a substituent may be, for example, a methyl group or a group represented by —CH₂—R₁₁. R₁₁ represents a halogen atom (such as a fluorine atom), a hydroxyl group, or a monovalent organic group, and examples thereof include an alkyl group having 5 or less carbon atoms that may be substituted with a halogen atom, an acyl group having 5 or less carbon atoms that may be substituted with a halogen atom, and an alkoxy group having 5 or less carbon atoms that may be substituted with a halogen atom; preferred is an alkyl group having 3 or less carbon atoms; and more preferred is a methyl group. Xa₁ is preferably a hydrogen atom, a methyl group, a trifluoromethyl group, or a hydroxymethyl group.

For T, examples of the divalent linking group include an alkylene group, an aromatic ring group, a —COO-Rt- group, and an —O-Rt- group. In the formulas, Rt represents an alkylene group or a cycloalkylene group.

T is preferably a single bond or a —COO-Rt- group. When T represents a —COO-Rt- group, Rt is preferably an alkylene group having 1 to 5 carbon atoms, and more preferably a —CH₂— group, a —(CH₂)₂— group, or a —(CH₂)₃— group.

For Rx₁ to Rx₃, the alkyl group is preferably an alkyl group having 1 to 4 carbon atoms such as a methyl group, an ethyl group, an n-propyl group, an isopropyl group, an n-butyl group, an isobutyl group, or a t-butyl group.

For Rx₁ to Rx₃, the cycloalkyl group is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

For the cycloalkyl group formed by bonding together two among Rx₁ to Rx₃, preferred are monocyclic cycloalkyl groups such as a cyclopentyl group and a cyclohexyl group, and also preferred are polycyclic cycloalkyl groups such as a norbornyl group, a tetracyclodecanyl group, a tetracyclododecanyl group, and an adamantyl group. In particular, preferred is a monocyclic cycloalkyl group having 5 to 6 carbon atoms.

In the cycloalkyl group formed by bonding together two among Rx₁ to Rx₃, for example, one of methylene groups constituting the ring may be replaced by a heteroatom such as an oxygen atom or a group having a heteroatom such as a carbonyl group.

For Rx₁ to Rx₃, the alkenyl group may be a vinyl group.

For Rx₁ to Rx₃, the aryl group may be a phenyl group.

In a preferred embodiment of the repeating unit represented by the general formula (AI), for example, Rx₁ is a methyl group or an ethyl group, and Rx₂ and Rx₃ are bonded together to form the above-described cycloalkyl group.

When such a group has a substituent, examples of the substituent include an alkyl group (having 1 to 4 carbon atoms), a halogen atom, a hydroxyl group, an alkoxy group (having 1 to 4 carbon atoms), a carboxyl group, and an alkoxycarbonyl group (having 2 to 6 carbon atoms). The substituent preferably has 8 or less carbon atoms.

The repeating unit represented by the general formula (AI) is preferably an acid decomposable (meth)acrylic acid tertiary alkyl ester-based repeating unit (a repeating unit in which Xa₁ represents a hydrogen atom or a methyl group, and T represents a single bond).

The resin (A) may have a single repeating unit (A-a) species alone, or may have two or more repeating unit (A-a) species.

The content of the repeating unit (A-a) (when two or more repeating unit (A-a) species are present, the total content thereof) relative to all the repeating units in the resin (A) is preferably 15 to 80 mol %, and more preferably 20 to 70 mol %.

The resin (A) preferably has, as the repeating unit (A-a), at least one repeating unit selected from the group consisting of repeating units represented by the following general formulas (A-VIII) to (A-XII).

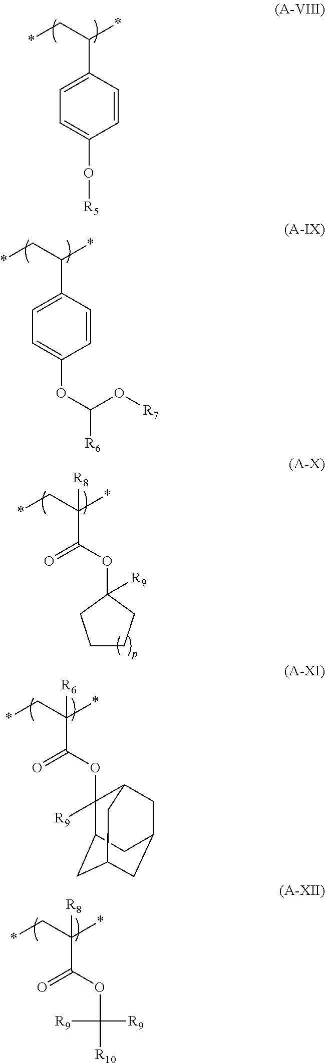

In the general formula (A-VIII), R₅ represents a tert-butyl group or a —CO—O-(tert-butyl) group.

In the general formula (A-IX), R₆ and R₇ each independently represent a monovalent organic group. Examples of the monovalent organic group include an alkyl group, a cycloalkyl group, an aryl group, an aralkyl group, and an alkenyl group.

In the general formula (A-X), p represents 1 or 2.

In the general formulas (A-X) to (A-XII), R₈ represents a hydrogen atom or an alkyl group having 1 to 3 carbon atoms, and R₉ represents an alkyl group having 1 to 3 carbon atoms.

In the general formula (A-XII), R₁₀ represents an alkyl group having 1 to 3 carbon atoms or an adamantyl group.

### Repeating Unit (A-1) Having Acid Group

The resin (A) may have a repeating unit (A-1) having an acid group.

The acid group is preferably an acid group having a pKa of 13 or less. The acid group preferably has an acid dissociation constant of 13 or less, more preferably 3 to 13, and still more preferably 5 to 10.

When the resin (A) has an acid group having a pKa of 13 or less, the content of the acid group in the resin (A) is not particularly limited, but is often 0.2 to 6.0 mmol/g. In particular, preferred is 0.8 to 6.0 mmol/g, more preferred is 1.2 to 5.0 mmol/g, and still more preferred is 1.6 to 4.0 mmol/g. When the content of the acid group is within such a range, development proceeds well, the pattern profile formed is more excellent, and higher resolution is also provided.

The acid group is preferably, for example, a carboxyl group, a hydroxyl group, a phenolic hydroxyl group, a fluorinated alcohol group (preferably a hexafluoroisopropanol group), a sulfonic group, a sulfonamide group, or an isopropanol group.

In the hexafluoroisopropanol group, one or more (preferably one or two) fluorine atoms may be substituted with groups other than fluorine atoms (such as alkoxycarbonyl groups). —C(CF₃)(OH)—CF₂— formed in this way is also preferred as the acid group. Alternatively, one or more fluorine atoms may be substituted with groups other than fluorine atoms, to form a ring including —C(CF₃)(OH)—CF₂ —.

The repeating unit (A-1) having an acid group is preferably a repeating unit different from the above-described repeating unit having a structure in which a polar group is protected with a leaving group that leaves by the action of an acid, and a repeating unit (A-2) described later and having a lactone group, a sultone group, or a carbonate group.

The repeating unit having an acid group may have a fluorine atom or an iodine atom.

The repeating unit having an acid group is preferably a repeating unit having a phenolic hydroxyl group, and more preferably a repeating unit represented by a formula (Y).

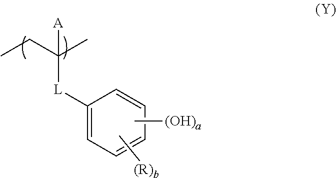

In the formula (Y), A represents a hydrogen atom, an alkyl group, a cycloalkyl group, a halogen atom, or a cyano group.

L represents a single bond or a divalent linking group having an oxygen atom. L is preferably a single bond.

R represents a halogen atom, an alkyl group, a cycloalkyl group, an aryl group, an alkenyl group, an aralkyl group, an alkoxy group, an alkylcarbonyloxy group, an alkylsulfonyloxy group, an alkyloxycarbonyl group, or an aryloxycarbonyl group; when there are a plurality of R's, they may be the same or different. When a plurality of R's are present, they may be bonded together to form a ring. R is preferably a hydrogen atom.

a represents an integer of 1 to 3.

b represents an integer of 0 to (5−a).

The following are examples of the repeating unit having an acid group. In the formulas, a represents 1 or 2.

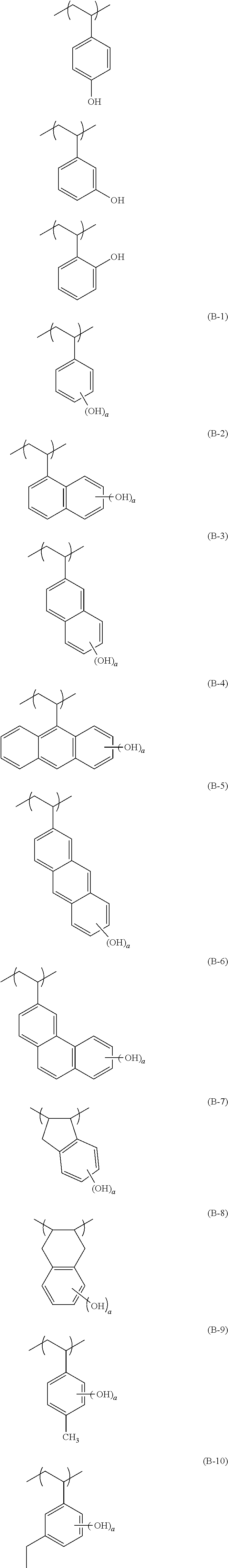

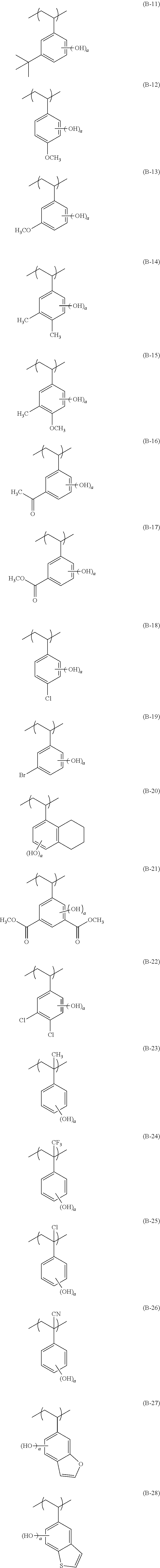

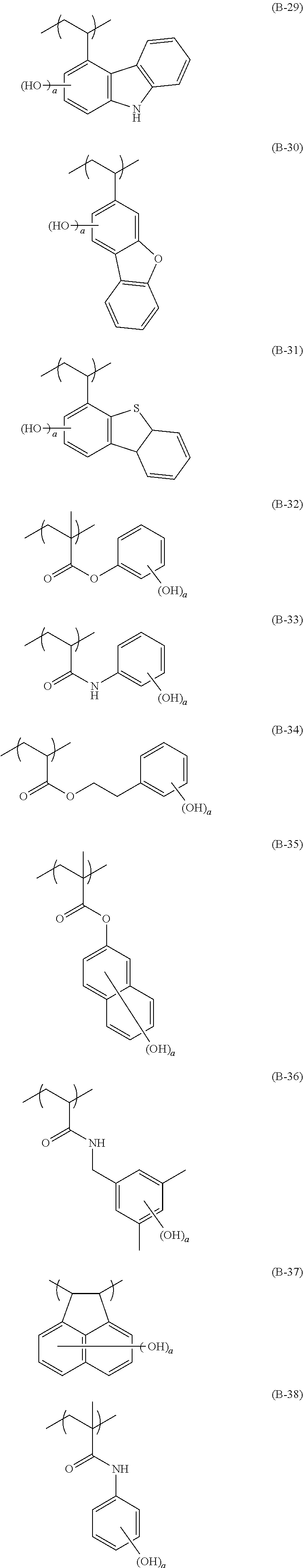

Other preferred examples of the repeating unit having an acid group include the repeating units having a phenolic hydroxyl group described in paragraphs 0089 to 0100 of JP2018-189758A.

When the resin (A) includes the repeating unit (A-1) having an acid group, the reference photosensitive composition and the photosensitive composition for measurement including the resin (A) are preferably used for KrF exposure, EB exposure, or EUV exposure. In such an embodiment, the content of the repeating unit having an acid group in the resin (A) relative to all the repeating units in the resin (A) is, for example, preferably 30 to 100 mol %, more preferably 40 to 100 mol %, and still more preferably 50 to 100 mol %. In another embodiment, for example, it is preferably 30 to 90 mol %, and more preferably 35 to 60 mol %.

### Repeating Unit (A-2) Having at Least One Selected from Group Consisting of Lactone Structure, Sultone Structure, Carbonate Structure, and Hydroxyadamantane Structure

The resin (A) may have a repeating unit (A-2) having at least one selected from the group consisting of a lactone structure, a carbonate structure, a sultone structure, and a hydroxyadamantane structure.

In the repeating unit having a lactone structure or a sultone structure, the lactone structure or the sultone structure is not particularly limited, but is preferably a 5- to 7-membered ring lactone structure or a 5- to 7-membered ring sultone structure, and more preferably a 5- to 7-membered ring lactone structure fused with another ring structure so as to form a bicyclo structure or a spiro structure, or a 5- to 7-membered ring sultone structure fused with another ring structure so as to form a bicyclo structure or a spiro structure.

Examples of the repeating unit having a lactone structure or a sultone structure include the repeating units described in paragraphs 0094 to 0107 of WO2016/136354A.

The resin (A) may have a repeating unit having a carbonate structure. The carbonate structure is preferably a cyclic carbonic ester structure.

Examples of the repeating unit having a carbonate structure include the repeating units described in paragraphs 0106 to 0108 of WO2019/054311A.

The resin (A) may have a repeating unit having a hydroxyadamantane structure. Examples of the repeating unit having a hydroxyadamantane structure include a repeating unit represented by the following general formula (AIIa).

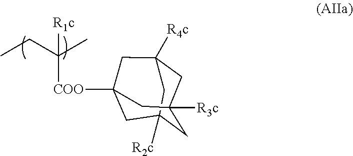

In the general formula (AIIa), R₁c represents a hydrogen atom, a methyl group, a trifluoromethyl group, or a hydroxymethyl group. R₂c to R₄c each independently represent a hydrogen atom or a hydroxyl group. Note that at least one of R₂c to R₄c represents a hydroxyl group. One or two among R₂c to R₄c are preferably hydroxyl groups, and the other is preferably a hydrogen atom.

### Repeating Unit Having Fluorine Atom or Iodine Atom

The resin (A) may have a repeating unit having a fluorine atom or an iodine atom.

Examples of the repeating unit having a fluorine atom or an iodine atom include the repeating units described in paragraphs 0080 to 0081 of JP2019-045864A.

### Repeating Unit Having Photoacid Generation Group

The resin (A) may have, as a repeating unit other than those described above, a repeating unit having a group that generates an acid upon irradiation with a radiation.

Examples of the repeating unit having a photoacid generation group include the repeating units described in paragraphs 0092 to 0096 of JP2019-045864A.

### Repeating Unit Having Alkali-Soluble Group

The resin (A) may have a repeating unit having an alkali-soluble group.

Examples of the alkali-soluble group include a carboxyl group, a sulfonamide group, a sulfonylimide group, a bissulfonylimide group, and an aliphatic alcohol substituted with an electron-withdrawing group at the α-position (for example, a hexafluoroisopropanol group), and preferred is a carboxyl group. When the resin (A) has a repeating unit having an alkali-soluble group, increased resolution is provided in the contact hole applications.

Examples of the repeating unit having an alkali-soluble group include a repeating unit in which an alkali-soluble group is directly bonded to the main chain of the resin, such as repeating units derived from acrylic acid and methacrylic acid, and a repeating unit in which an alkali-soluble group is bonded to the main chain of the resin via a linking group. Note that the linking group may have a monocyclic or polycyclic cyclic hydrocarbon structure.

The repeating unit having an alkali-soluble group is preferably a repeating unit derived from acrylic acid or methacrylic acid.

### Repeating Unit Not Having Acid Decomposable Group or Polar Group

The resin (A) may further have a repeating unit not having an acid decomposable group or a polar group. The repeating unit not having an acid decomposable group or a polar group preferably has an alicyclic hydrocarbon structure.

Examples of the repeating unit not having an acid decomposable group or a polar group include the repeating units described in paragraphs 0236 to 0237 of US2016/0026083A and the repeating units described in paragraph 0433 of US2016/0070167A.

The resin (A) may have, in addition to the above-described repeating structural units, various repeating structural units for the purpose of adjusting dry etching resistance, suitability for the standard developer, adhesiveness to the substrate, resist profile, resolving power, heat resistance, sensitivity, or the like.

### Properties of Resin (A)

In the resin (A), all the repeating units are preferably constituted by repeating units derived from (meth)acrylate-based monomers. In this case, any of a resin in which all the repeating units are derived from methacrylate-based monomers, a resin in which all the repeating units are derived from acrylate-based monomers, and a resin in which all the repeating units are derived from a methacrylate-based monomer and an acrylate-based monomer can be used. The content of the repeating unit derived from an acrylate-based monomer is preferably 50 mol % or less relative to all the repeating units in the resin (A).

When the reference photosensitive composition and the photosensitive composition for measurement are used for argon fluoride (ArF) exposure, from the viewpoint of transmittance of the ArF beam, the resin (A) preferably has substantially no aromatic group. More specifically, the content of the repeating unit having an aromatic group relative to all the repeating units of the resin (A) is preferably 5 mol % or less, more preferably 3 mol % or less, and ideally 0 mol %; in other words, the resin (A) still more preferably does not have a repeating unit having an aromatic group.

When the reference photosensitive composition and the photosensitive composition for measurement are used for ArF exposure, the resin (A) preferably has a monocyclic or polycyclic alicyclic hydrocarbon structure, and preferably does not include a fluorine atom or a silicon atom.

When the reference photosensitive composition and the photosensitive composition for measurement are used for krypton fluoride (KrF) exposure, EB exposure, or EUV exposure, the resin (A) preferably has a repeating unit having an aromatic hydrocarbon group, and more preferably has a repeating unit having a phenolic hydroxyl group.

Examples of the repeating unit having a phenolic hydroxyl group include the above-described repeating unit exemplified as the repeating unit (A-1) having an acid group and a repeating unit derived from hydroxystyrene (meth)acrylate.

When the reference photosensitive composition and the photosensitive composition for measurement are used for KrF exposure, EB exposure, or EUV exposure, the resin (A) also preferably has a repeating unit having a structure in which the hydrogen atom of a phenolic hydroxyl group is protected by a group (leaving group) that is decomposed to leave by the action of an acid.

When the reference photosensitive composition and the photosensitive composition for measurement are used for KrF exposure, EB exposure, or EUV exposure, the content of the repeating unit having an aromatic hydrocarbon group included in the resin (A) relative to all the repeating units in the resin (A) is preferably 30 to 100 mol %, more preferably 35 to 100 mol %, still more preferably 40 to 100 mol %, and yet more preferably 50 to 100 mol %.

The resin (A) can be synthesized in accordance with an ordinary method (for example, radical polymerization).

The resin (A) has a weight-average molecular weight (Mw) of preferably 1,000 to 200,000, more preferably 3,000 to 20,000, and still more preferably 5,000 to 15,000. When the weight-average molecular weight (Mw) of the resin (A) is set to 1,000 to 200,000, degradation of heat resistance and dry etching resistance can be prevented, and further, degradation of developability and degradation of film-formability due to an increase in viscosity can be prevented. Note that the weight-average molecular weight (Mw) of the resin (A) is a polystyrene-equivalent value measured by the above-described GPC method.

The dispersity (molecular weight distribution) of the resin (A) is ordinarily 1 to 5, preferably 1 to 3, and more preferably 1.1 to 2.0. The smaller the dispersity, the better the resolution and the resist profile, and further, the smoother the side wall of the pattern and the higher the roughness performance.

In the reference photosensitive composition and the photosensitive composition for measurement, the content of the resin (A) relative to the total solid content of the reference photosensitive composition and the photosensitive composition for measurement is preferably 50 to 99.9 mass %, and more preferably 60 to 99.0 mass %.

Such resins (A) may be used alone or in combination of two or more thereof.

### Photoacid Generator

The reference photosensitive composition and the photosensitive composition for measurement include a photoacid generator (B). The photoacid generator (B) is not particularly limited as long as it is a compound that generates an acid upon irradiation with a radiation.

The photoacid generator (B) may be in the form of a low molecular weight compound or may be in the form of being incorporated into a part of a polymer. The form of a low molecular weight compound and the form of being incorporated into a part of a polymer may be used in combination.

When the photoacid generator (B) is in the form of a low molecular weight compound, the weight-average molecular weight (Mw) thereof is preferably 3000 or less, more preferably 2000 or less, and still more preferably 1000 or less.

When the photoacid generator (B) is in the form of being incorporated into a part of a polymer, it may be incorporated into a part of the resin (A) or may be incorporated into a resin different from the resin (A).

The photoacid generator (B) is preferably in the form of a low molecular weight compound.

The photoacid generator (B) is not particularly limited as long as it is a publicly known photoacid generator, but is preferably a compound that generates an organic acid upon irradiation with a radiation, and more preferably a photoacid generator having a fluorine atom or an iodine atom in the molecule.

Examples of the organic acid include sulfonic acids (such as aliphatic sulfonic acids, aromatic sulfonic acids, and camphorsulfonic acids), carboxylic acids (such as aliphatic carboxylic acids, aromatic carboxylic acids, and aralkyl carboxylic acids), carbonylsulfonylimidic acid, bis(alkylsulfonyl) imidic acids, and tris(alkylsulfonyl) methide acids.

The volume of acid generated from the photoacid generator (B) is not particularly limited, but is, from the viewpoint of suppressing diffusion of acid generated upon exposure to unexposed regions and improving resolution, preferably 240 Å³ or more, more preferably 305 Å³ or more, still more preferably 350 Å³ or more, and particularly preferably 400 Å³ or more. Note that, from the viewpoint of sensitivity or solubility in coating solvents, the volume of the acid generated from the photoacid generator (B) is preferably 1500 Å³ or less, more preferably 1000 Å³ or less, and still more preferably 700 Å³ or less.

The value of the volume is determined using “WinMOPAC” manufactured by FUJITSU LIMITED. The value of the volume is calculated in the following manner: first, the chemical structure of the acid according to each example is input; subsequently, this structure serving as the initial structure is subjected to molecular force field calculation using the MM (Molecular Mechanics) 3 method to thereby determine the most stable conformation of each acid; subsequently, the most stable conformation is subjected to molecular orbital calculation using the PM (Parameterized Model Number) 3 method to thereby calculate the “accessible volume” of each acid.

The structure of the acid generated from the photoacid generator (B) is not particularly limited, but, from the viewpoint of suppressing diffusion of the acid and improving the resolution, the interaction between the acid generated from the photoacid generator (B) and the resin (A) is preferably strong. From this point of view, when the acid generated from the photoacid generator (B) is an organic acid, it preferably has, in addition to an organic acid group such as a sulfonic group, a carboxylic group, a carbonylsulfonylimidic group, a bissulfonylimidic group, or a trissulfonylmethide group, a polar group.

Examples of the polar group include an ether group, an ester group, an amide group, an acyl group, a sulfo group, a sulfonyloxy group, a sulfonamide group, a thioether group, a thioester group, a urea group, a carbonate group, a carbamate group, a hydroxyl group, and a mercapto group.

The number of polar groups that the generated acid has is not particularly limited, but is preferably one or more, and more preferably two or more. Note that, from the viewpoint of suppressing excessive development, the number of polar groups is preferably less than 6, and more preferably less than 4.

In particular, the photoacid generator (B) is preferably a photoacid generator composed of an anionic moiety and a cationic moiety.

Examples of the photoacid generator (B) include the photoacid generators described in paragraphs 0144 to 0173 of JP2019-045864A.

The content of the photoacid generator (B) is not particularly limited, but is, relative to the total solid content of the reference photosensitive composition and the photosensitive composition for measurement, preferably 5 to 50 mass %, more preferably 5 to 40 mass %, and still more preferably 5 to 35 mass %.

Such photoacid generators (B) may be used alone or in combination of two or more thereof. When two or more photoacid generators (B) are used in combination, the total amount thereof is preferably within such a range.

### Acid Diffusion Control Agent (C)

The reference photosensitive composition and the photosensitive composition for measurement may include an acid diffusion control agent (C).

The acid diffusion control agent (C) acts as a quencher that traps an acid generated from the photoacid generator (B) or the like upon exposure and suppresses the reaction of the acid decomposable resin in the unexposed regions due to an excess of the generated acid. Examples of the acid diffusion control agent (C) include a basic compound (CA), a basic compound (CB) that undergoes reduction or loss of the basicity upon irradiation with a radiation, an onium salt (CC) that serves as a weak acid relative to the photoacid generator (B), a low molecular weight compound (CD) having a nitrogen atom and having a group that leaves by the action of an acid, and an onium salt compound (CE) having a nitrogen atom in the cationic moiety.

In the reference photosensitive composition and the photosensitive composition for measurement, a publicly known acid diffusion control agent can be appropriately used. For example, publicly known compounds disclosed in paragraphs [0627] to [0664] of US2016/0070167A, paragraphs [0095] to [0187] of US2015/0004544A, paragraphs [0403] to [0423] of US2016/0237190A, and paragraphs [0259] to [0328] of US2016/0274458A can be suitably used as the acid diffusion control agent (C).

Examples of the basic compound (CA) include the repeating units described in paragraphs 0188 to 0208 of JP2019-045864A.

In the reference photosensitive composition and the photosensitive composition for measurement, the onium salt (CC) that serves as a weak acid relative to the photoacid generator (B) can be used as the acid diffusion control agent (C).

When the photoacid generator (B) is used in combination with an onium salt that generates an acid that serves as a weak acid relative to the acid generated from the photoacid generator (B), the acid generated from the photoacid generator (B) upon irradiation with an actinic ray or a radiation collides with an onium salt having an unreacted weak acid anion, so that the weak acid is released by salt exchange to generate an onium salt having a strong acid anion. In this process, the strong acid is exchanged with the weak acid having a lower catalytic activity, so that the acid is apparently deactivated and the acid diffusion can be controlled.

Examples of the onium salt that serves as a weak acid relative to the photoacid generator (B) include the onium salts described in paragraphs 0226 to 0233 of JP2019-070676A.

When the reference photosensitive composition and the photosensitive composition for measurement include the acid diffusion control agent (C), the content of the acid diffusion control agent (C) (when a plurality of acid diffusion control agents (C) are present, the total content thereof) relative to the total solid content of the reference photosensitive composition and the photosensitive composition for measurement is preferably 0.1 to 10.0 mass % and more preferably 0.1 to 5.0 mass %.

Such acid diffusion control agents (C) may be used alone or in combination of two or more thereof. When two or more acid diffusion control agents (C) are used in combination, the total amount thereof is preferably within such a range.

### Hydrophobic Resin (E)

The reference photosensitive composition and the photosensitive composition for measurement may include, as a hydrophobic resin (E), a hydrophobic resin different from the resin (A).

The hydrophobic resin (E) is preferably designed so as to be localized in the surface of the resist film, but unlike surfactants, the hydrophobic resin (E) does not necessarily have a hydrophilic group in the molecule, and does not necessarily contribute to homogeneous mixing of a polar substance and a nonpolar substance.

Advantages provided by adding the hydrophobic resin (E) include control of the static and dynamic contact angles of the resist film surface with respect to water, suppression of outgassing, and the like.

The hydrophobic resin (E), from the viewpoint of localized distribution to the film surface layer, preferably has any one or more of “a fluorine atom”, “a silicon atom”, and “a CH₃ partial structure included in a side chain portion of the resin”, and more preferably has two or more thereof. The hydrophobic resin (E) preferably has a hydrocarbon group having 5 or more carbon atoms. The resin may have such a group in the main chain or, as a substituent, in a side chain.

In the case where the hydrophobic resin (E) includes a fluorine atom and/or a silicon atom, the fluorine atom and/or the silicon atom in the hydrophobic resin may be included in the main chain of the resin or may be included in a side chain.

When the hydrophobic resin (E) has a fluorine atom, the partial structure having a fluorine atom is preferably an alkyl group having a fluorine atom, a cycloalkyl group having a fluorine atom, or an aryl group having a fluorine atom.

The alkyl group having a fluorine atom (preferably having 1 to 10 carbon atoms, and more preferably having 1 to 4 carbon atoms) is a linear or branched alkyl group in which at least one hydrogen atom is substituted with a fluorine atom, and may further have a substituent other than a fluorine atom.

The cycloalkyl group having a fluorine atom is a monocyclic or polycyclic cycloalkyl group in which at least one hydrogen atom is substituted with a fluorine atom, and may further have a substituent other than a fluorine atom.

Examples of the aryl group having a fluorine atom include an aryl group such as a phenyl group or a naphthyl group in which at least one hydrogen atom is substituted with a fluorine atom, and the aryl group may further have a substituent other than a fluorine atom.

Examples of repeating unit having a fluorine atom or a silicon atom include the repeating units exemplified in paragraph 0519 of US2012/0251948A.

As described above, the hydrophobic resin (E) also preferably has a CH₃ partial structure in the side chain portion.

The CH₃ partial structure of the side chain portion in the hydrophobic resin includes a CH₃ partial structure having an ethyl group, a propyl group, or the like.

On the other hand, a methyl group directly bonded to the main chain of the hydrophobic resin (E) (for example, an a-methyl group of a repeating unit having a methacrylic acid structure) makes a small contribution to the surface localized distribution of the hydrophobic resin (E) due to the influence of the main chain, and hence is not included in the CH₃ partial structure in the present invention.

For the hydrophobic resin (E), reference can be made to the descriptions in paragraphs [0348] to [0415] of JP2014-010245A and the contents of which are incorporated herein by reference.

As the hydrophobic resin (E), the resins described in JP2011-248019A, JP2010-175859A, and JP2012-032544A can also be preferably used.

In a case where the reference photosensitive composition and the photosensitive composition for measurement include the hydrophobic resin (E), the content of the hydrophobic resin (E) relative to the total solid content of the reference photosensitive composition and the photosensitive composition for measurement is preferably 0.01 to 20 mass % and more preferably 0.1 to 15 mass %.

### Solvent (F)

The reference photosensitive composition and the photosensitive composition for measurement may include a solvent (F).

In a case where the reference photosensitive composition and the photosensitive composition for measurement are radiation-sensitive resin compositions for EUV exposure, the solvent (F) preferably includes at least one of (F1) a propylene glycol monoalkyl ether carboxylate or (F2) at least one selected from the group consisting of a propylene glycol monoalkyl ether, a lactate, an acetate, an alkoxypropionate, a chain ketone, a cyclic ketone, a lactone, and an alkylene carbonate. In this case, the solvent may further include a component other than the components (F1) and (F2).

The solvent including at least one of the component (F1) or (F2) is preferably used in combination with the above-described resin (A) because the coatability of the reference photosensitive composition and the photosensitive composition for measurement is improved, and a pattern having a small number of development defects can be formed.

When the reference photosensitive composition and the photosensitive composition for measurement are radiation-sensitive resin compositions for ArF, examples of the solvent (F) include organic solvents such as alkylene glycol monoalkyl ether carboxylates, alkylene glycol monoalkyl ethers, alkyl lactates, alkyl alkoxypropionates, cyclic lactones (preferably having 4 to 10 carbon atoms), monoketone compounds (preferably having 4 to 10 carbon atoms) that may include a ring, alkylene carbonates, alkyl alkoxyacetates, and alkyl pyruvates.

The content of the solvent (F) in the reference photosensitive composition and the photosensitive composition for measurement is preferably set so that the solid content concentration becomes 0.5 to 40 mass %.

In one embodiment of the reference photosensitive composition and the photosensitive composition for measurement, the solid content concentration is also preferably 10 mass % or more.

### Surfactant (H)

The reference photosensitive composition and the photosensitive composition for measurement may include a surfactant (H). When the surfactant (H) is included, a pattern having higher adhesiveness and less development defects can be formed.

The surfactant (H) is preferably a fluorine-based and/or a silicone-based surfactant.

Examples of the fluorine-based and/or silicone-based surfactants include the surfactants described in paragraph [0276] of US2008/0248425A.

Instead of the above-described publicly known surfactants, the surfactant (H) may be synthesized using a fluoroaliphatic compound produced by a telomerization method (also referred to as a telomer method) or an oligomerization method (also referred to as an oligomer method). Specifically, a polymer including a fluoroaliphatic group derived from the fluoroaliphatic compound may be used as the surfactant (H). The fluoroaliphatic compound can be synthesized by, for example, the method described in JP2002-90991A.

Such surfactants (H) may be used alone or in combination of two or more thereof.

The content of the surfactant (H) relative to the total solid content of the reference photosensitive composition and the photosensitive composition for measurement is preferably 0.0001 to 2 mass %, and more preferably 0.0005 to 1 mass %.

### Other Additives

The reference photosensitive composition and the photosensitive composition for measurement may further include a crosslinking agent, an alkali-soluble resin, a dissolution inhibiting compound, a dye, a plasticizer, a photosensitizer, a light absorber, and/or a compound that promotes solubility in a developer.

### EXAMPLES

Hereinafter, features of the present invention will be described more specifically with reference to Examples. In the following Examples, materials, reagents, amounts and ratios of substances, procedures, and the like can be appropriately changed without departing from the spirit and scope of the present invention. Therefore, the scope of the present invention is not limited to the following Examples.

### Preparation of Compositions

Components described in Table 1 below were mixed together to prepare compositions.

In Table 1, the “Content (mass %)” columns represent the contents of components relative to the total solid contents in the compositions. The solid content concentrations of the compositions were each 1.5 mass %.

In Table 1, R represents, for the monomers having an acid decomposable group constituting the repeating units included in the acid decomposable resins, the solubility index (R) and the solubility index difference (ΔR) before and after acid leaving. Note that R_{B} and ΔR_{B} respectively represent, for the monomer represented by a formula B below, the solubility index (R) and the solubility index difference (ΔR) before and after acid leaving. Further, R_{C} and ΔR_{C} respectively represent, for the monomer represented by a formula C below, the solubility index (R) and the solubility index difference (ΔR) before and after acid leaving.

TABLE 1

| | Acid | | Photoacid | | Acid diffusion | | | | | | | |
|---|---|---|---|---|---|---|---|---|---|---|---|---|
| | decomposable resin | | generator | | control agent | | Solvent | | R | | ΔR | |
| | | Content | | Content | | Content | | Mixing | (MPa)^{1/2} | | (MPa)^{1/2} | |
| | Type | (mass %) | Type | (mass %) | Type | (mass %) | Type | mass ratio | R_{B} | R_{C} | ΔR_{B} | ΔR_{C} |
| Composition 1 | A-1 | 77.9 | B-1 | 19.4 | C-1 | 2.7 | F-1/F-2/F-4/F-3 | 85/7/7/1 | 4.26 | 3.17 | 4.24 | 5.32 |
| Composition 2 | A-2 | 77.9 | B-1 | 19.4 | C-1 | 2.7 | F-1/F-2/F-4/F-3 | 85/7/7/1 | 4.26 | 3.17 | 4.24 | 5.32 |

Acid decomposable resins A-1 and A-2 are resins obtained by radical polymerization of monomers represented by formulas below and are resins having repeating units derived from the monomers. The contents of the repeating units, molecular weight, and dispersity will be described in Table 2.

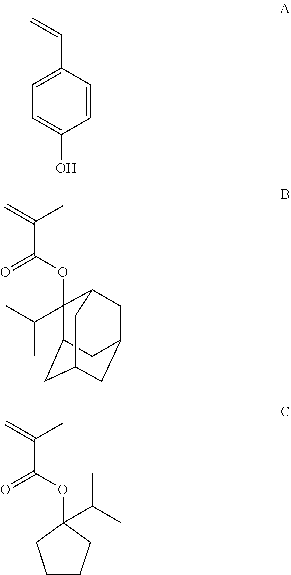

TABLE 2

| | Repeating unit content | | | | |
|---|---|---|---|---|---|
| | (mass %) | | | | Dispersity |
| | A | B | C | Mw | (Mw/Mn) |
| Resin A-1 | 40 | 30 | 30 | 6500 | 1.60 |
| Resin A-2 | 35 | 25 | 40 | 6800 | 1.58 |

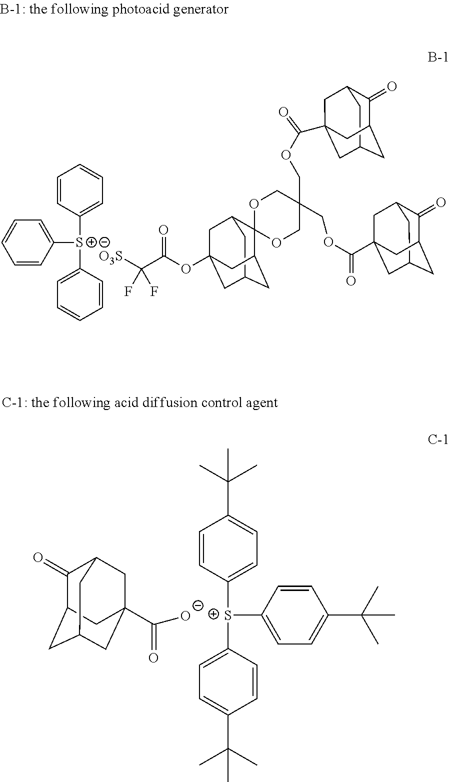

F-1: propylene glycol monomethyl ether acetate (PGMEA)
F-2: propylene glycol monomethyl ether (PGME)
F-3: γ-butyrolactone
F-4: 2-heptanone

### Preparation of Treatment Liquids

Mixing was performed so as to satisfy the components and contents described in Table below to thereby prepare treatment liquids of Examples and Comparative Examples.

The content of the metal X was adjusted by continuously passing such a prepared treatment liquid through a filter such that a predetermined content was reached or by adding the metal X. The content of water in each treatment liquid was adjusted to 20 to 1000 mass ppm relative to the total mass of the treatment liquid. The contents of the various components were calculated from the charged amounts or measured using the above-described method for measuring the contents of various components.

Note that, in each treatment liquid, the content of the organic solvent corresponds to the balance other than the components described in Table below and water.

### Aliphatic Hydrocarbon

### Undecane

### Ester-Based Solvent

Butyl acetate

### Aromatic Hydrocarbons

C1: 1-ethyl-3,5-dimethyl-benzene (C₁₀H₁₄)
C2: 1,2,3,5-tetramethyl-benzene (C₁₀H₁₄)
C3: (1-methylbutyl)-benzene (C₁₁H₁₆)
C4: 1,2,3,4-tetrahydro-naphthalene (C₁₀H₁₂)

In Table 3 below, descriptions indicate the following.

In “Organic solvent”, the “Content (a)” column indicates the mass content of an aliphatic hydrocarbon relative to the total mass of an organic solvent defined as 100.

In “Organic solvent”, the “Content (b)” column indicates the mass content of an ester-based solvent relative to the total mass of an organic solvent defined as 100.

Thus, for example, in Treatment liquid 1, the mass ratio of the aliphatic hydrocarbon to the ester-based solvent is 10:90.

In “Aromatic hydrocarbon”, the “total” column indicates the total content of the aromatic hydrocarbons C1 to C4 relative to the total mass of a treatment liquid.

In “Aromatic hydrocarbon”, the “C1” to “C4” columns respectively indicate the contents (mass ppm) of the aromatic hydrocarbons C1 to C4 relative to the total mass of a treatment liquid.

In “Metal X”, the “total” column indicates the total content (mass ppt) of Fe, Ni, and Al relative to the total mass of a treatment liquid.

In “Metal X”, the “Fe”, “Ni”, and “Al” columns respectively indicate the contents (mass ppt) of Fe, Ni, and Al relative to the total mass of a treatment liquid.

The “(c)/(e)” column indicates the mass ratio of the content of the aromatic hydrocarbons (total content of the aromatic hydrocarbons C1 to C4) to the content of the metal X (total content of Fe, Ni, and Al) (content of aromatic hydrocarbons/content of metal X (total content of Fe, Ni, and Al)). “E+n” represents “×10ⁿ” and “E-n” represents “×10⁻ⁿ”. n represents an integer of 0 or more. Specifically, “1.50E+10” represents “1.50×10¹⁰”. Note that “E+n” above and “E−n” above have the same meanings in other columns.

TABLE 3

| | Organic solvent | | | | | | | | | | | | | |
|---|---|---|---|---|---|---|---|---|---|---|---|---|---|---|
| | Aliphatic | | | | Aromatic hydrocarbon (mass ppm) | | | | | Metal X (mass ppt) | | | | |
| | hydrocarbon | Ester-based | Content | Content | total | | | | | total | | | | |
| | (a) | solvent (b) | (a) | (b) | (c) | C1 | C2 | C3 | C4 | (e) | Fe | Ni | Al | (c)/(e) |
| Treatment | Undecane | Butyl acetate | 10 | 90 | 9000 | 4000 | 3000 | 1000 | 1000 | 0.60 | 0.35 | 0.15 | 0.10 | 1.50E+10 |
| liquid 1 | | | | | | | | | | | | | | |
| Treatment | Undecane | Butyl acetate | 10 | 90 | 60 | 20 | 20 | 10 | 10 | 1000 | 800 | 100 | 100 | 6.00E+04 |
| liquid 2 | | | | | | | | | | | | | | |
| Treatment | Undecane | Butyl acetate | 10 | 90 | 80 | 40 | 24 | 10 | 6 | 2000 | 1200 | 500 | 300 | 4.00E+04 |
| liquid 3 | | | | | | | | | | | | | | |
| Treatment | Undecane | Butyl acetate | 10 | 90 | 9800 | 6000 | 1800 | 1200 | 800 | 0.28 | 0.20 | 0.05 | 0.03 | 3.50E+10 |
| liquid 4 | | | | | | | | | | | | | | |
| Treatment | Undecane | Butyl acetate | 10 | 90 | 8550 | 3100 | 2000 | 2000 | 1450 | 0.45 | 0.25 | 0.10 | 0.10 | 1.90E+10 |
| liquid 5 | | | | | | | | | | | | | | |
| Treatment | Undecane | Butyl acetate | 10 | 90 | 60 | 20 | 10 | 20 | 10 | 1177 | 870 | 207 | 100 | 5.10E+04 |
| liquid 6 | | | | | | | | | | | | | | |

### Example 1-1

### Test 1A

### Test 1A-1

The composition 1 was applied onto a QCM electrode and baked at 100° C. for 60 seconds to form a resist film having a film thickness of 35 nm. Thus, a QCM electrode having a resist film was produced.

Subsequently, the QCM electrode having the resist film was brought into contact with the treatment liquid 1 to thereby remove the resist film. In this process, the change in the frequency of the quartz oscillator was monitored, and the time (T) required from the start of contact with the treatment liquid 1 until the change in the frequency became constant was measured.

The film thickness (35 nm) of the resist film before the treatment was divided by the measured time (T) (35 nm/T s) to thereby calculate the dissolution rate (nm/s) of the resist film to obtain measurement data. The dissolution rate was 40 nm/s.

An underlayer film forming composition AL-412 (manufactured by Brewer Science, Inc.) was applied onto a 12-inch silicon wafer and baked at 205° C. for 60 seconds to form an underlayer film having a film thickness of 20 nm. This was coated with the composition 1 prepared above and baking (PB) at 90° C. for 60 seconds was performed to form a resist film having a film thickness of 35 nm.

The obtained silicon wafer having a resist film was subjected to pattern irradiation using an EUV exposure apparatus (manufactured by ASML, EUV Scanner NXE-3400, NA: 0.33, Quadrupole, outer sigma: 0.68, inner sigma: 0.36). Note that the reticle employed was a photo mask having a line size=20 nm and line:space=1:1. Subsequently, baking (PEB) at 100° C. for 60 seconds was performed; subsequently, puddling using the treatment liquid 1 was performed for 30 seconds to achieve development; and the wafer was rotated at a rotational rate of 4000 rpm for 30 seconds to thereby obtain a line-and-space pattern having a pitch of 40 nm.

The LWR of the obtained pattern was measured and found to be 3.0 nm.

### Test 1A-2

Subsequently, the resist composition 1 was used to perform once more the same procedures as described above.

Specifically, the composition 1 was applied onto the QCM electrode and baked at 100° C. for 60 seconds to form a resist film having a film thickness of 35 nm. Thus, a QCM electrode having a resist film was produced. Subsequently, the QCM electrode having the resist film was brought into contact with the treatment liquid 1 to thereby remove the resist film. In this process, the change in the frequency of the quartz oscillator was monitored, and the time (T) required from the start of contact with the treatment liquid 1 until the change in the frequency became constant was measured.

The film thickness (35 nm) of the resist film before the treatment was divided by the measured time (T) to thereby calculate the dissolution rate (nm/s) of the resist film. The dissolution rate was 42 nm/s.

An underlayer film forming composition AL-412 (manufactured by Brewer Science, Inc.) was applied onto a 12-inch silicon wafer and baked at 205° C. for 60 seconds to form an underlayer film having a film thickness of 20 nm. This was coated with the composition 1 prepared above and baking (PB) at 90° C. for 60 seconds was performed to form a resist film having a film thickness of 35 nm.

The obtained silicon wafer having a resist film was subjected to pattern irradiation using an EUV exposure apparatus (manufactured by ASML, EUV Scanner NXE-3400, NA: 0.33, Quadrupole, outer sigma: 0.68, inner sigma: 0.36). Note that the reticle employed was a photo mask having a line size=20 nm and line:space=1:1. Subsequently, baking (PEB) at 100° C. for 60 seconds was performed; subsequently, puddling using the treatment liquid 1 was performed for 30 seconds to achieve development; and the wafer was rotated at a rotational rate of 4000 rpm for 30 seconds to thereby obtain a line-and-space pattern having a pitch of 40 nm.

The LWR of the obtained pattern was measured and found to be 3.1 nm.

In the above-described results, after the procedure of using the treatment liquid 1 to remove the resist film formed using the composition 1, the dissolution rate of the resist film was measured twice; the dissolution rate at the first time was 40 nm/s and the dissolution rate at the second time was 42 nm/s; both of these results were substantially the same, and the ratio of the dissolution rates (dissolution rate at the second time/dissolution rate at the first time) was 1.05. Further, the result of LWR in the pattern formation at the first time was 3.0 nm, and the result of LWR in the pattern formation at the second time was 3.1 nm; both of these results were substantially the same, and the difference in LWR was 0.1 nm.

### Test 2A

An evaluation was performed by the same procedures as in Test 1A above except that the composition 1 used in Test 1A-2 of Test 1A was replaced by the composition 2.

After the procedure of using the treatment liquid 1 to remove the resist film formed using the composition 1, the dissolution rate of the resist film was 40 nm/s; after the procedure of using the treatment liquid 1 to remove the resist film formed using the composition 2, the dissolution rate of the resist film was 48 nm/s; the ratio of the dissolution rates (dissolution rate at the second time/dissolution rate at the first time) was 1.20, which was larger than that in Test 1A above.

In addition, the result of LWR in the pattern formation at the first time using the composition 1 was 3.0 nm; the result of LWR in the pattern formation at the second time using the composition 2 was 3.6 nm; and the difference in LWR was 0.6 nm, which was larger than that in Test 1A above.

The above-described results of Test 1A and Test 2A have demonstrated the following: when the ratio of the dissolution rates is small, the difference in LWR is also small; and when the ratio of the dissolution rates is large, the difference in LWR is also large. This result has demonstrated that the dissolution rate is closely correlated with the evaluation result of LWR.

On the basis of the results, for example, the ratio of dissolution rates of 0.9 to 1.1 is set as the allowable range, and, instead of the composition 1 used in Test 1A-2 of Test 1A above, another photosensitive composition is tested; when the ratio of the dissolution rates is in the allowable range, the result of LWR can be determined to be also similar to the result of LWR of the resist composition 1.

### Example 1-2

An experiment was performed in the same manner as in Example 1-1 except that the treatment liquid 1 was replaced by the treatment liquid 2. The results, which will be described in Table 4, have demonstrated that, as in Example 1-1, the dissolution rate is closely correlated with the evaluation result of LWR.

### Example 1-3

An experiment was performed in the same manner as in Example 1-1 except that the treatment liquid 1 was replaced by the treatment liquid 5. The results, which will be described in Table 4, have demonstrated that, as in Example 1-1, the dissolution rate is closely correlated with the evaluation result of LWR.

### Example 1-4

An experiment was performed in the same manner as in Example 1-1 except that the treatment liquid 1 was replaced by the treatment liquid 6. The results, which will be described in Table 4, have demonstrated that, as in Example 1-1, the dissolution rate is closely correlated with the evaluation result of LWR.

### Comparative Example 1-1

An experiment was performed in the same manner as in Test 2A of Example 1-1 above in which the treatment liquid 1 was replaced by the treatment liquid 3; as described in Table 4, after the procedure of using the treatment liquid 3 to remove the resist film formed using the composition 2, the dissolution rate of the resist film was 42 nm/s, and the result of LWR in the pattern formation at the second time using the composition 2 was 4.0 nm.

As described in Table 4, in Comparative Example 1-1, while the ratio of the dissolution rates (dissolution rate at the second time/dissolution rate at the first time) was 1.05 and they were close to each other, the difference between the LWR in the pattern formation at the first time using the composition 1 and the LWR in the pattern formation at the second time using the composition 2 was as large as 1.0 nm; thus, there was no correlation between the dissolution rate and the difference in LWR.

This result has demonstrated that, in the case of not using the predetermined treatment liquid, photosensitive compositions cannot be tested.

### Comparative Example 1-2

An experiment was performed in the same manner as in Test 2A of Example 1-1 above in which the treatment liquid 1 was replaced by the treatment liquid 4; as described in Table 4, after the procedure of using the treatment liquid 4 to remove the resist film formed using the composition 2, the dissolution rate of the resist film was 38 nm/s, and the result of LWR in the pattern formation at the second time using the composition 2 was 4.2 nm.

As described in Table 4, in Comparative Example 1-2, while the ratio of the dissolution rates (dissolution rate at the second time/dissolution rate at the first time) was 0.95 and they were close to each other, the difference between the LWR in the pattern formation at the first time using the composition 1 and the LWR in the pattern formation at the second time using the composition 2 was as large as 1.2 nm; thus, there was no correlation between the dissolution rate and the difference in LWR.

This result has demonstrated that, in the case of not using the predetermined treatment liquid, photosensitive compositions cannot be tested.

In Table 4, in the “Correlation” column, cases where there is a relationship between dissolution rate and the difference in LWR (the cases where there is a correlation) are described as “Present”, and cases where there is no relationship are described as “Absent”.

TABLE 4

| | | | | | | | | | | Determination (difference | | |
|---|---|---|---|---|---|---|---|---|---|---|---|---|
| | | | | | | | | | | between “For measurement” | | |
| | | | | | | | | | | and “For reference”) | | |
| | | | | For reference | | | For measurement | | | Ratio of | | |
| | | Treatment liquid | | | Disso- | | | Disso- | | disso- | LWR | |
| | | | Aromatic | | lution | | | lution | | lution | difference | |
| | | | hydro- | | rate | LWR | | rate | LWR | rates | (nm) | |
| | | | carbon/ | | (nm/s) | (nm) | | (nm/s) | (nm) | (UDR2)/ | (L2) − | |
| | Test | Type | metal X | Composition | (UDR1) | (L1) | Composition | (UDR2) | (L2) | (UDR1) | (L1) | Correlation |
| Example 1-1 | 1A | Treatment | 1.50E+10 | Composition 1 | 40 | 3.0 | Composition 1 | 42 | 3.1 | 1.05 | 0.1 | Present |
| | | liquid 1 | | | | | | | | | | |
| | 2A | Treatment | 1.50E+10 | Composition 1 | 40 | 3.0 | Composition 2 | 48 | 3.6 | 1.20 | 0.6 | |
| | | liquid 1 | | | | | | | | | | |
| Example 1-2 | 1A | Treatment | 6.00E+04 | Composition 1 | 40 | 3.0 | Composition 1 | 42 | 3.1 | 1.05 | 0.1 | Present |
| | | liquid 2 | | | | | | | | | | |
| | 2A | Treatment | 6.00E+04 | Composition 1 | 40 | 3.0 | Composition 2 | 48 | 3.6 | 1.20 | 0.6 | |
| | | liquid 2 | | | | | | | | | | |
| Example 1-3 | 1A | Treatment | 1.90E+10 | Composition 1 | 40 | 3.0 | Composition 1 | 42 | 3.1 | 1.05 | 0.1 | Present |
| | | liquid 5 | | | | | | | | | | |
| | 2A | Treatment | 1.90E+10 | Composition 1 | 40 | 3.0 | Composition 2 | 48 | 3.6 | 1.20 | 0.6 | |
| | | liquid 5 | | | | | | | | | | |
| Example 1-4 | 1A | Treatment | 5.10E+04 | Composition 1 | 40 | 3.0 | Composition 1 | 42 | 3.1 | 1.05 | 0.1 | Present |
| | | liquid 6 | | | | | | | | | | |
| | 2A | Treatment | 5.10E+04 | Composition 1 | 40 | 3.0 | Composition 2 | 48 | 3.6 | 1.20 | 0.6 | |
| | | liquid 6 | | | | | | | | | | |
| Comparative | 2A | Treatment | 4.00E+04 | Composition 1 | 40 | 3.0 | Composition 2 | 42 | 4.0 | 1.05 | 1.0 | Absent |
| Example 1-1 | | liquid 3 | | | | | | | | | | |
| Comparative | 2A | Treatment | 3.50E+10 | Composition 1 | 40 | 3.0 | Composition 2 | 38 | 4.2 | 0.95 | 1.2 | |
| Example 1-2 | | liquid 4 | | | | | | | | | | |

Table 4 above has demonstrated that the test method of the present invention provides the desired advantages.

In Example 1-1, a treatment liquid having the same formula as the treatment liquid 1 was used except that the ratio of undecane to butyl acetate was 5:95; this has also demonstrated that there is the same correlation as in Example 1-1.

In Example 1-1, a treatment liquid having the same formula as the treatment liquid 1 was used except that the ratio of undecane to butyl acetate was 15:85; this has also demonstrated that there is the same correlation as in Example 1-1.

In Example 1-1, a treatment liquid having the same formula as the treatment liquid 1 was used except that the ratio of undecane to butyl acetate was 20:80; this has also demonstrated that there is the same correlation as in Example 1-1.

In Example 1-1, a treatment liquid having the same formula as the treatment liquid 1 was used except that the ratio of undecane to butyl acetate was 40:60; this has also demonstrated that there is the same correlation as in Example 1-1.

In Example 1-1, a treatment liquid having the same formula as the treatment liquid 1 was used except that the ratio of undecane to butyl acetate was 60:40; this has also demonstrated that there is the same correlation as in Example 1-1.

In Example 1-1, a treatment liquid having the same formula as the treatment liquid 1 was used except that undecane was replaced by decane; this has also demonstrated that there is the same correlation as in Example 1-1.

In Example 1-1, a treatment liquid having the same formula as the treatment liquid 1 was used except that undecane was replaced by dodecane; this has also demonstrated that there is the same correlation as in Example 1-1.

In Example 1-1, a treatment liquid having the same formula as the treatment liquid 1 was used except that butyl acetate was replaced by isoamyl acetate; this has also demonstrated that there is the same correlation as in Example 1-1.

In Example 1-1, a treatment liquid having the same formula as the treatment liquid 1 was used except that butyl acetate was replaced by isoamyl formate; this has also demonstrated that there is the same correlation as in Example 1-1.

In addition, in Example 1-2, a treatment liquid having the same formula as the treatment liquid 2 was used except that undecane was replaced by decane; this has also demonstrated that, as in Example 1-2, the dissolution rate is closely correlated with the evaluation result of LWR.

In addition, in Comparative Example 1-1, a treatment liquid having the same formula as the treatment liquid 3 was used except that undecane was replaced by decane; this has also demonstrated that, as in Comparative Example 1-1, there is no correlation between the dissolution rate and the difference in LWR.

In addition, in Comparative Example 1-2, a treatment liquid having the same formula as the treatment liquid 4 was used except that undecane was replaced by decane; this has also demonstrated that, as in Comparative Example 1-2, there is no correlation between the dissolution rate and the difference in LWR.

In addition, in Example 1-2, a treatment liquid having the same formula as the treatment liquid 2 was used except that undecane was replaced by dodecane; this has also demonstrated that, as in Example 1-2, the dissolution rate is closely correlated with the evaluation result of LWR.

In addition, in Comparative Example 1-1, a treatment liquid having the same formula as the treatment liquid 3 was used except that undecane was replaced by dodecane; this has also demonstrated that, as in Comparative Example 1-1, there is no correlation between the dissolution rate and the difference in LWR.

In addition, in Comparative Example 1-2, a treatment liquid having the same formula as the treatment liquid 4 was used except that undecane was replaced by dodecane; this has also demonstrated that, as in Comparative Example 1-2, there is no correlation between the dissolution rate and the difference in LWR.

In addition, in Example 1-2, a treatment liquid having the same formula as the treatment liquid 2 was used except that butyl acetate was replaced by amyl acetate; this has also demonstrated that, as in Example 1-2, the dissolution rate is closely correlated with the evaluation result of LWR.

In addition, in Comparative Example 1-1, a treatment liquid having the same formula as the treatment liquid 3 was used except that butyl acetate was replaced by amyl acetate; this has also demonstrated that, as in Comparative Example 1-1, there is no correlation between the dissolution rate and the difference in LWR.

In addition, in Comparative Example 1-2, a treatment liquid having the same formula as the treatment liquid 4 was used except that butyl acetate was replaced by amyl acetate; this has also demonstrated that, as in Comparative Example 1-2, there is no correlation between the dissolution rate and the difference in LWR.

In addition, in Example 1-2, a treatment liquid having the same formula as the treatment liquid 2 was used except that butyl acetate was replaced by isoamyl formate; this has also demonstrated that, as in Example 1-2, the dissolution rate is closely correlated with the evaluation result of LWR.

In addition, in Comparative Example 1-1, a treatment liquid having the same formula as the treatment liquid 3 was used except that butyl acetate was replaced by isoamyl formate; this has also demonstrated that, as in Comparative Example 1-1, there is no correlation between the dissolution rate and the difference in LWR.

In addition, in Comparative Example 1-2, a treatment liquid having the same formula as the treatment liquid 4 was used except that butyl acetate was replaced by isoamyl formate; this has also demonstrated that, as in Comparative Example 1-2, there is no correlation between the dissolution rate and the difference in LWR.

In Example 1-1, a treatment liquid having the same formula as the treatment liquid 1 was used except that the mass ratio of the aromatic hydrocarbon content to the metal X content was 5.0×10⁷; this has also demonstrated that there is the same correlation as in Example 1-1.

In Example 1-1, a composition having the same formula as the composition 1 was used except that the acid decomposable resin A-1 was replaced by an acid decomposable resin A-3 (see below); this has also demonstrated that there is the same correlation as in Example 1-1.

The acid decomposable resin A-3 is a resin obtained by radical polymerization of monomers represented by formulas below and is a resin having repeating units derived from the monomers.

Table 5 below will describe, for the acid decomposable resin A-3, the contents of the repeating units, the molecular weight, and the dispersity, and the solubility indexes (R) and the solubility index differences (ΔR) of the monomers having an acid decomposable group. Note that R_{X} and ΔR_{X} respectively represent, for the monomer represented by a formula X below, the solubility index (R) and the solubility index difference (ΔR) before and after acid leaving. Further, R_{Y} and ΔR_{Y} respectively represent, for the monomer represented by a formula Y below, the solubility index (R) and the solubility index difference (ΔR) before and after acid leaving.

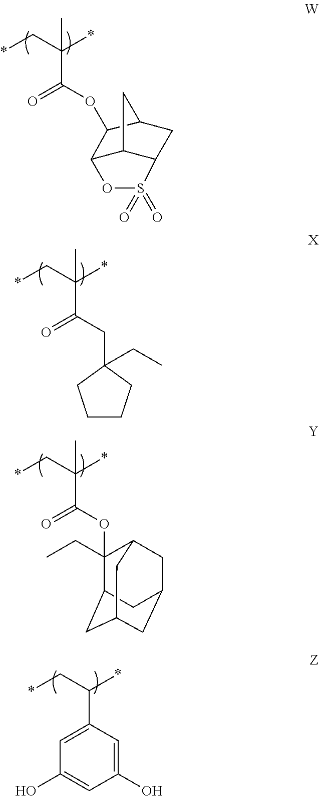

TABLE 5

| | | | | | | | Solubility | | Solubility index | |
|---|---|---|---|---|---|---|---|---|---|---|
| | Repeating unit content (mass %) | | | | | Dispersity | index (R) | | difference (ΔR) | |
| | W | X | Y | Z | Mw | (Mw/Mn) | R_{X} | R_{Y} | ΔR_{X} | ΔR_{Y} |
| Resin A-3 | 30 | 25 | 30 | 15 | 8123 | 1.64 | 2.68 | 3.78 | 5.82 | 4.71 |

In Example 1-1, a composition having the same formula as the composition 1 was used except that the acid decomposable resin A-1 was replaced by the acid decomposable resin A-1 and the acid decomposable resin A-3 in a weight ratio of 7:3; this has also demonstrated that there is the same correlation as in Example 1-1.

In Example 1-1, a composition having the same formula as the composition 1 was used except that the photoacid generator B-1 was replaced by a photoacid generator B-2 (see below); this has also demonstrated that there is the same correlation as in Example 1-1.

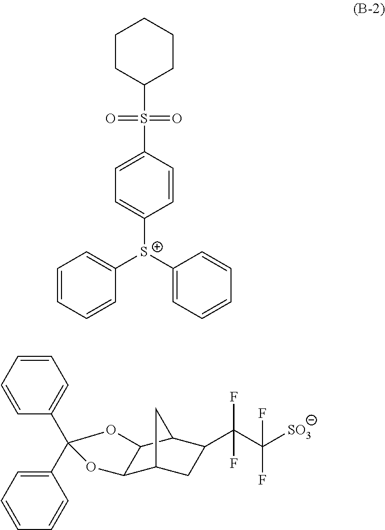

In Example 1-1, a composition having the same formula as the composition 1 was used except that the photoacid generator B-1 was replaced by the photoacid generator B-1 and the photoacid generator B-2 in a weight ratio of 1:1; this has also demonstrated that there is the same correlation as in Example 1-1.

### Example 2-1

### Test 1B

### Test 1B-1

An underlayer film forming composition AL-412 (manufactured by Brewer Science, Inc.) was applied onto a 12-inch silicon wafer and baked at 205° C. for 60 seconds to form an underlayer film having a film thickness of 20 nm. This was coated with the composition 1 prepared above and baking (PB) at 90° C.for 60 seconds was performed to form a resist film having a film thickness of 35 nm. In this way, two silicon wafers having a resist film were produced. Note that the above-described procedures were repeated twice to produce silicon wafers having a resist film.

One of the obtained silicon wafers having a resist film was subjected to, using an EUV Scanner NXE-3400 (NA: 0.33) manufactured by ASML, open-frame exposure (exposure of the entire surface of the resist film) at an exposure dose of 30 mJ/cm². Subsequently, baking (PEB) was performed at 110° C.for 60 seconds, and an optical interference-type film thickness measuring apparatus (“VM-3200 (product name)”, manufactured by SCREEN Semiconductor Solutions Co., Ltd.) was used to measure the film thickness (T1) of the resist film after PEB.

Subsequently, the silicon wafer having the exposed resist film was immersed in the treatment liquid 1 to perform puddle development for 30 seconds, and subsequently the silicon wafer having the resist film was taken out from the treatment liquid 1 and rotated at a rotational rate of 4000 rpm for 30 seconds. The optical interference-type film thickness measuring apparatus was used again to measure the film thickness (T2) of the resist film after development in the obtained silicon wafer.

The value obtained by subtracting the film thickness (T2) of the resist film after development from the resist film thickness (T1) before development was divided by the developing time (30 seconds) ((T1−T2) nm/30 s) to calculate the dissolution rate (nm/s) of the resist film, to obtain the measurement data. The dissolution rate was 0.100 nm/s.

The other silicon wafer having a resist film was subjected to pattern irradiation using an EUV exposure apparatus (manufactured by ASML, EUV Scanner NXE-3400, NA: 0.33, Quadrupole, outer sigma: 0.68, inner sigma: 0.36). Note that the reticle employed was a photo mask having a line size =20 nm and line:space =1:1. Subsequently, baking (PEB) at 100° C. for 60 seconds was performed; subsequently, puddling using the treatment liquid 1 was performed for 30 seconds to achieve development; and the wafer was rotated at a rotational rate of 4000 rpm for 30 seconds to thereby obtain a line-and-space pattern having a pitch of 40 nm.

The LWR of the obtained pattern was measured and found to be 3.0 nm.

### Test 1B-2

Subsequently, the resist composition 1 was used to perform once more the same procedures as described above.

Specifically, an underlayer film forming composition SHB-A940 (manufactured by Shin-Etsu Chemical Co., Ltd.) was applied onto a 12-inch silicon wafer and baked at 205° C. for 60 seconds to form an underlayer film having a film thickness of 20 nm. This was coated with the composition 1 prepared above and baking (PB) at 90° C. for 60 seconds was performed to form a resist film having a film thickness of 35 nm. Thus, a silicon wafer having a resist film was produced. Note that the above-described procedures were repeated twice to produce two silicon wafers having a resist film.

One of the obtained silicon wafers having a resist film was subjected to, using an EUV Scanner NXE-3400 manufactured by ASML, NA: 0.33, open-frame exposure (exposure of the entire surface of the resist film) at an exposure dose of 30 mJ/cm². Subsequently, baking (PEB) was performed at 110° C. for 60 seconds, and an optical interference-type film thickness measuring apparatus (“VM-3200 (product name)”, manufactured by SCREEN Semiconductor Solutions Co., Ltd.) was used to measure the film thickness (T1) of the resist film after PEB.

Subsequently, the silicon wafer having the exposed resist film was immersed in the treatment liquid 1 to perform puddle development for 30 seconds, and subsequently the silicon wafer having the resist film was taken out from the treatment liquid 1 and rotated at a rotational rate of 4000 rpm for 30 seconds. The optical interference-type film thickness measuring apparatus was used again to measure the film thickness (T2) of the resist film after development in the obtained silicon wafer.

The value obtained by subtracting the film thickness (T2) of the resist film after development from the resist film thickness (T1) before development was divided by the developing time (30 seconds) ((T1−T2) nm/30 s) to calculate the dissolution rate (nm/s) of the resist film, to obtain the measurement data. The dissolution rate was 0.105 nm/s.

The other silicon wafer having a resist film was subjected to pattern irradiation using an EUV exposure apparatus (manufactured by ASML, EUV Scanner NXE-3400, NA: 0.33, Quadrupole, outer sigma: 0.68, inner sigma: 0.36). Note that the reticle employed was a photo mask having a line size=20 nm and line:space=1:1. Subsequently, baking (PEB) at 100° C. for 60 seconds was performed; subsequently, puddling using the treatment liquid I was performed for 30 seconds to achieve development; and the wafer was rotated at a rotational rate of 4000 rpm for 30 seconds to thereby obtain a line-and-space pattern having a pitch of 40 nm.

The LWR of the obtained pattern was measured and found to be 3.1 nm.

In the above-described results, after the procedure of exposing the entire surface of the resist film formed using the composition 1 and subsequently bringing the resist film into contact with the treatment liquid 1, the dissolution rate of the resist film was measured twice; the dissolution rate at the first time was 0.100 nm/s, and the dissolution rate at the second time was 0.105 nm/s; both of these results were substantially the same, and the ratio of the dissolution rates (dissolution rate at the second time/dissolution rate at the first time) was 1.05. Further, the result of LWR in the pattern formation at the first time was 3.0 nm, and the result of LWR in the pattern formation at the second time was 3.1 nm; both of these results were substantially the same, and the difference in LWR was 0.1 nm.

### Test 2B

An evaluation was performed by the same procedures as in Test 1B above except that the composition I used in Test 1B-2 of Test 1B was replaced by the composition 2.

After the procedure of exposing the entire surface of the resist film formed using the composition 1 and subsequently bringing the resist film into contact with the treatment liquid 1, the dissolution rate of the resist film was 0.100 nm/s; after the procedure of exposing the entire surface of the resist film formed using the composition 2 and subsequently bringing the resist film into contact with the treatment liquid 1, the dissolution rate of the resist film was 0.120 nm/s; the ratio of the dissolution rates (dissolution rate at the second time/dissolution rate at the first time) was 1.20, which was larger than that in Test 1B above.

In addition, the result of LWR in the pattern formation at the first time using the composition 1 was 3.0 nm; the result of LWR in the pattern formation at the second time using the composition 2 was 3.6 nm; and the difference in LWR was 0.6 nm, which was larger than that in Test 1B above.

The above-described results of Test 1B and Test 2B have demonstrated the following: when the ratio of the dissolution rates is small, the difference in LWR is also small; and when the ratio of the dissolution rates is large, the difference in LWR is also large. This result has demonstrated that the dissolution rate is closely correlated with the evaluation result of LWR.

On the basis of the results, for example, the ratio of dissolution rates of 0.9 to 1.1 is set as the allowable range, and, instead of the composition 1 used in Test 1B-2 of Test 1B above, another photosensitive composition is tested; when the ratio of the dissolution rates is in the allowable range, the result of LWR can be determined to be also similar to the result of LWR of the resist composition 1.

### Example 2-2

An experiment was performed in the same manner as in Example 2-1 except that the treatment liquid 1 was replaced by the treatment liquid 2. The results, which will be described in Table 6, have demonstrated that, as in Example 2-1, the dissolution rate is closely correlated with the evaluation result of LWR.

### Comparative Example 2-1

An experiment was performed in the same manner as in Test 2B of Example 2-1 above in which the treatment liquid 1 was replaced by the treatment liquid 3; as described in Table 6, after the procedure of exposing the entire surface of the resist film formed using the composition 2 and subsequently bringing the resist film into contact with the treatment liquid 3, the dissolution rate of the resist film was 0.105 nm/s, and the result of LWR in the pattern formation at the second time using the composition 2 was 4.0 nm.

As described in Table 6, in Comparative Example 2-1, while the ratio of the dissolution rates (dissolution rate at the second time/dissolution rate at the first time) was 1.05 and they were close to each other, the difference between the LWR in the pattern formation at the first time using the composition 1 and the LWR in the pattern formation at the second time using the composition 2 was as large as 1.0 nm; thus, there was no correlation between the dissolution rate and the difference in LWR.

This result has demonstrated that, in the case of not using the predetermined treatment liquid, photosensitive compositions cannot be tested.

### Comparative Example 2-2

An experiment was performed in the same manner as in Test 2B of Example 2-1 above in which the treatment liquid 1 was replaced by the treatment liquid 4; as described in Table 6, after the procedure of exposing the entire surface of the resist film formed using the composition 2 and subsequently bringing the resist film into contact with the treatment liquid 4, the dissolution rate of the resist film was 0.095 nm/s, and the result of LWR in the pattern formation at the second time using the composition 2 was 4.2 nm.

As described in Table 6, in Comparative Example 2-2, while the ratio of the dissolution rates (dissolution rate at the second time/dissolution rate at the first time) was 0.95 and they were close to each other, the difference between the LWR in the pattern formation at the first time using the composition 1 and the LWR in the pattern formation at the second time using the composition 2 was as large as 1.2 nm; thus, there was no correlation between the dissolution rate and the difference in LWR.

This result has demonstrated that, in the case of not using the predetermined treatment liquid, photosensitive compositions cannot be tested.

In Table 6, in the “Correlation” column, cases where there is a relationship between dissolution rate and the difference in LWR (the cases where there is a correlation) are described as “Present”, and cases where there is no relationship are described as “Absent”.

TABLE 6

| | | | | | | | | | | Determination (difference | | |
|---|---|---|---|---|---|---|---|---|---|---|---|---|
| | | | | | | | | | | between “For measurement” | | |
| | | | | | | | | | | and “For reference”) | | |
| | | | | For reference | | | For measurement | | | Ratio of | | |
| | | Treatment liquid | | | Disso- | | | Disso- | | disso- | LWR | |
| | | | Aromatic | | lution | | | lution | | lution | difference | |
| | | | hydro- | | rate | LWR | | rate | LWR | rates | (nm) | |
| | | | carbon/ | | (nm/s) | (nm) | | (nm/s) | (nm) | (UDR2)/ | (L2) − | |
| | Test | Type | metal X | Composition | (UDR1) | (L1) | Composition | (UDR2) | (L2) | (UDR1) | (L1) | Correlation |
| Example 2-1 | 1B | Treatment | 1.50E+10 | Composition 1 | 0.100 | 3.0 | Composition 1 | 0.105 | 3.1 | 1.05 | 0.1 | Present |
| | | liquid 1 | | | | | | | | | | |
| | 2B | Treatment | 1.50E+10 | Composition 1 | 0.100 | 3.0 | Composition 2 | 0.120 | 3.6 | 1.20 | 0.6 | |
| | | liquid 1 | | | | | | | | | | |
| Example 2-2 | 1B | Treatment | 6.00E+04 | Composition 1 | 0.100 | 3.0 | Composition 1 | 0.105 | 3.1 | 1.05 | 0.1 | Present |
| | | liquid 2 | | | | | | | | | | |
| | 2B | Treatment | 6.00E+04 | Composition 1 | 0.100 | 3.0 | Composition 2 | 0.120 | 3.6 | 1.20 | 0.6 | |
| | | liquid 2 | | | | | | | | | | |
| Example 2-3 | 1B | Treatment | 1.90E+10 | Composition 1 | 0.100 | 3.0 | Composition 1 | 0.105 | 3.1 | 1.05 | 0.1 | Present |
| | | liquid 5 | | | | | | | | | | |
| | 2B | Treatment | 1.90E+10 | Composition 1 | 0.100 | 3.0 | Composition 2 | 0.120 | 3.6 | 1.20 | 0.6 | |
| | | liquid 5 | | | | | | | | | | |
| Example 2-4 | 1B | Treatment | 5.10E+04 | Composition 1 | 0.100 | 3.0 | Composition 1 | 0.105 | 3.1 | 1.05 | 0.1 | Present |
| | | liquid 6 | | | | | | | | | | |
| | 2B | Treatment | 5.10E+04 | Composition 1 | 0.100 | 3.0 | Composition 2 | 0.120 | 3.6 | 1.20 | 0.6 | |
| | | liquid 6 | | | | | | | | | | |
| Comparative | 2B | Treatment | 4.00E+04 | Composition 1 | 0.100 | 3.0 | Composition 2 | 0.105 | 4.0 | 1.05 | 1.0 | Absent |
| Example 2-1 | | liquid 3 | | | | | | | | | | |
| Comparative | 2B | Treatment | 3.50E+10 | Composition 1 | 0.100 | 3.0 | Composition 2 | 0.095 | 4.2 | 0.95 | 1.2 | |
| Example 2-2 | | liquid 4 | | | | | | | | | | |

Table 6 above has demonstrated that the test method of the present invention provides the desired advantages.

In Example 2-1, a treatment liquid having the same formula as the treatment liquid 1 was used except that the ratio of undecane to butyl acetate was 5:95; this has also demonstrated that there is the same correlation as in Example 2-1.

In Example 2-1, a treatment liquid having the same formula as the treatment liquid 1 was used except that the ratio of undecane to butyl acetate was 15:85; this has also demonstrated that there is the same correlation as in Example 2-1.

In Example 2-1, a treatment liquid having the same formula as the treatment liquid 1 was used except that the ratio of undecane to butyl acetate was 20:80; this has also demonstrated that there is the same correlation as in Example 2-1.

In Example 2-1, a treatment liquid having the same formula as the treatment liquid 1 was used except that the ratio of undecane to butyl acetate was 40:60; this has also demonstrated that there is the same correlation as in Example 2-1.

In Example 2-1, a treatment liquid having the same formula as the treatment liquid 1 was used except that the ratio of undecane to butyl acetate was 60:40; this has also demonstrated that there is the same correlation as in Example 2-1.

In Example 2-1, a treatment liquid having the same formula as the treatment liquid 1 was used except that undecane was replaced by decane; this has also demonstrated that there is the same correlation as in Example 2-1.

In Example 2-1, a treatment liquid having the same formula as the treatment liquid 1 was used except that undecane was replaced by dodecane; this has also demonstrated that there is the same correlation as in Example 2-1.

In Example 2-1, a treatment liquid having the same formula as the treatment liquid 1 was used except that butyl acetate was replaced by isoamyl acetate; this has also demonstrated that there is the same correlation as in Example 2-1.

In Example 2-1, a treatment liquid having the same formula as the treatment liquid 1 was used except that butyl acetate was replaced by isoamyl formate; this has also demonstrated that there is the same correlation as in Example 2-1.

In Example 2-1, a treatment liquid having the same formula as the treatment liquid 1 was used except that the mass ratio of the aromatic hydrocarbon content to the metal X content was 5.0×10⁷; this has also demonstrated that there is the same correlation as in Example 2-1.

In Example 2-1, a composition having the same formula as the composition 1 was used except that the acid decomposable resin A-1 was replaced by the acid decomposable resin A-3; this has also demonstrated that there is the same correlation as in Example 2-1.

In Example 2-1, a composition having the same formula as the composition 1 was used except that the acid decomposable resin A-1 was replaced by the acid decomposable resin A-1 and the acid decomposable resin A-3 in a weight ratio of 7:3; this has also demonstrated that there is the same correlation as in Example 2-1.

In Example 2-1, a composition having the same formula as the composition 1 was used except that the photoacid generator B-1 was replaced by the photoacid generator B-2; this has also demonstrated that there is the same correlation as in Example 2-1.

In Example 2-1, a composition having the same formula as the composition 1 was used except that the photoacid generator B-1 was replaced by the photoacid generator B-1 and the photoacid generator B-2 in a weight ratio of 1:1; this has also demonstrated that there is the same correlation as in Example 2-1.

### REFERENCE SIGNS LIST

S10, S12, S14, S16, S20, S21, S22, S24 Steps
S30, S31, S32, S34, S40, S22, S24 Steps
S40, S42, S44 Steps

What is claimed is:

1. A method for testing a photosensitive composition, the method comprising:
a step 1 of using a reference photosensitive composition including an acid decomposable resin having a group that is decomposed by an action of an acid to generate a polar group and a photoacid generator, to form a resist film on a substrate 1, bringing the resist film on the substrate 1 into contact with a treatment liquid, and measuring a dissolution rate of the resist film on the substrate 1, to obtain reference data;
a step 2 of using a photosensitive composition for measurement including components of the same types as types of components included in the reference photosensitive composition, to form a resist film on a substrate 2, bringing the resist film on the substrate 2 into contact with a treatment liquid, and measuring a dissolution rate of the resist film on the substrate 2, to obtain measurement data; and
a step 3 of performing comparison between the reference data and the measurement data to determine whether or not an allowable range is satisfied,
wherein the treatment liquid includes an aromatic hydrocarbon, an organic solvent, and a metal X,
the organic solvent does not include the aromatic hydrocarbon and includes an aliphatic hydrocarbon,
the metal X is at least one metal selected from the group consisting of Al, Fe, and Ni, and
a mass ratio of a content of the aromatic hydrocarbon to a content of the metal X is 5.0×10⁴ to 2.0×10¹⁰.

2. The method for testing a photosensitive composition according to claim 1, wherein, in the step 3, when the measurement data is out of the allowable range, component adjustment of the photosensitive composition for measurement is performed.

3. The method for testing a photosensitive composition according to claim 1, wherein, in the step 1 and the step 2, the resist film on the substrate 1 and the resist film on the substrate 2 are each an exposed resist film provided by forming the resist film and subsequently subjecting an entire surface of the resist film to exposure.

4. The method for testing a photosensitive composition according to claim 3, wherein the exposure in the step 1 and the step 2 is performed using any one of a KrF excimer laser beam, an ArF excimer laser beam, an electron beam, and an extreme ultraviolet ray.

5. The method for testing a photosensitive composition according to claim 1, wherein the acid decomposable resin includes a repeating unit having a phenolic hydroxyl group.

6. The method for testing a photosensitive composition according to claim 1, wherein the aliphatic hydrocarbon is undecane, and
the organic solvent further includes butyl acetate.

7. The method for testing a photosensitive composition according to claim 6, wherein a ratio of a content of the butyl acetate to a content of the undecane is 65/35 to 99/1.

8. The method for testing a photosensitive composition according to claim 7, wherein the ratio of the content of the butyl acetate to the content of the undecane is 90/10.

9. The method for testing a photosensitive composition according to claim 1, wherein the acid decomposable resin has a repeating unit derived from a monomer having a group that is decomposed by an action of an acid to generate a polar group,
the monomer all has a solubility index (R) of 2.0 to 5.0 (MPa)^{1/2}, the solubility index (R) being represented by a formula (1) and based on Hansen solubility parameters relative to the treatment liquid,
at least one of the monomer has a solubility index difference (ΔR) before and after acid leaving of 4.0 (MPa)^{1/2} or more,
$$R = {( 4 {( δ d 1 - δ d 2 )}^{2} + {( δ p 1 - δ p 2 )}^{2} + {( δ h 1 - δ h 2 )}^{2} )}^{1 / 2} \qquad Formula ( 1 )$$
δd1 represents a dispersion term in the Hansen solubility parameters of the monomer,
δp1 represents a polar term in the Hansen solubility parameters of the monomer,
δh1 represents a hydrogen-bonding term in the Hansen solubility parameters of the monomer,
δd2 represents a dispersion term in Hansen solubility parameters of the treatment liquid,
δp2 represents a polar term in the Hansen solubility parameters of the treatment liquid, and
δh2 represents a hydrogen-bonding term in the Hansen solubility parameters of the treatment liquid.

10. The method for testing a photosensitive composition according to claim 1, wherein the content of the aromatic hydrocarbon relative to a total mass of the treatment liquid is 1 mass % or less.

11. A method for producing a photosensitive composition, the method comprising the method for testing a photosensitive composition according to claim 1.

12. The method for testing a photosensitive composition according to claim 2, wherein, in the step 1 and the step 2, the resist film on the substrate 1 and the resist film on the substrate 2 are each an exposed resist film provided by forming the resist film and subsequently subjecting an entire surface of the resist film to exposure.

13. The method for testing a photosensitive composition according to claim 12, wherein the exposure in the step 1 and the step 2 is performed using any one of a KrF excimer laser beam, an ArF excimer laser beam, an electron beam, and an extreme ultraviolet ray.

14. The method for testing a photosensitive composition according to claim 2, wherein the acid decomposable resin includes a repeating unit having a phenolic hydroxyl group.

15. The method for testing a photosensitive composition according to claim 2, wherein the aliphatic hydrocarbon is undecane, and
the organic solvent further includes butyl acetate.

16. The method for testing a photosensitive composition according to claim 15, wherein a ratio of a content of the butyl acetate to a content of the undecane is 65/35 to 99/1.

17. The method for testing a photosensitive composition according to claim 16, wherein the ratio of the content of the butyl acetate to the content of the undecane is 90/10.

18. The method for testing a photosensitive composition according to claim 2, wherein the acid decomposable resin has a repeating unit derived from a monomer having a group that is decomposed by an action of an acid to generate a polar group,
the monomer all has a solubility index (R) of 2.0 to 5.0 (MPa)^{1/2}, the solubility index (R) being represented by a formula (1) and based on Hansen solubility parameters relative to the treatment liquid,
at least one of the monomer has a solubility index difference (ΔR) before and after acid leaving of 4.0 (MPa)^{1/2} or more,
$$R = {( 4 {( δ d 1 - δ d 2 )}^{2} + {( δ p 1 - δ p 2 )}^{2} + {( δ h 1 - δ h 2 )}^{2} )}^{1 / 2} \qquad Formula ( 1 )$$
δd1 represents a dispersion term in the Hansen solubility parameters of the monomer,
δp1 represents a polar term in the Hansen solubility parameters of the monomer,
δh1 represents a hydrogen-bonding term in the Hansen solubility parameters of the monomer,
δd2 represents a dispersion term in Hansen solubility parameters of the treatment liquid,
δp2 represents a polar term in the Hansen solubility parameters of the treatment liquid, and
δh2 represents a hydrogen-bonding term in the Hansen solubility parameters of the treatment liquid.

19. The method for testing a photosensitive composition according to claim 2, wherein the content of the aromatic hydrocarbon relative to a total mass of the treatment liquid is 1 mass % or less.

20. A method for producing a photosensitive composition, the method comprising the method for testing a photosensitive composition according to claim 2.
